(19) United States
(12) Patent Application Publication
(10) Pub. No.: US 2023/0056927 A1
(43) Pub. Date: Feb. 23, 2023

(54) A METHOD FOR PRODUCING OF A MATERIAL LAYER OR OF A MULTI-LAYER STRUCTURE COMPRISING LITHIUM BY UTILIZING LASER ABLATION COATING

(71) Applicant: Pulsedeon Oy, Tampere (FI)

(72) Inventors: Jari LIIMATAINEN, Tampere (FI); Ville KEKKONEN, Tampere (FI)

(73) Assignee: Pulsedeon Oy, Tampere (FI)

(21) Appl. No.: 17/796,906

(22) PCT Filed: Feb. 23, 2021
(86) PCT No.: PCT/FI2021/050132

§ 371 Date: Aug. 2, 2022

(30) Foreign Application Priority Data
Feb. 24, 2020 (FI) 20207034

(51) Int. Cl. H01M 4/04; H01M 10/052; C23C 14/16; C23C 14/28; C23C 14/52

(52) U.S. Cl. CPC H01M 4/0423; H01M 10/052; H01M 4/0404; C23C 14/16; C23C 14/28; C23C 14/52

(57) ABSTRACT

A method is for manufacturing materials for electrochemical energy storage devices. A deposition method based on laser ablation is utilised in the manufacturing of at least one material layer including lithium. The process is controlled using measurement information that is obtained from the spectrum of the electromagnetic radiation generated by laser ablation. A roll-to-roll method can be used in the deposition, in which the substrate (15, 32, 44, 64, 75, 85) to be coated is directed from one roll (31a) to the second roll (31 b), and the deposition takes place in the area between the rolls (31a-b). In addition, turning and/or moving mirrors (21) can be used to direct laser beam (12, 41, 71a-d, 81a-d) as a beam line array (23) to the surface of the target (13, 42a-b, 72a-d, 82a-d, 82A-D).

### CROSS-REFERENCE TO RELATED APPLICATION(S)

This application is a National Stage Application of PCT/FI2021/050132, filed 23 Feb. 2021, which claims benefit of Serial No. 20207034, filed 24 Feb. 2020 in Finland, and which applications are incorporated herein by reference. To the extent appropriate, a claim of priority is made to each of the above disclosed applications.

### FIELD OF THE INVENTION

The invention is related to electrochemical energy storage devices utilising lithium such as batteries and capacitors, to their structure, and to manufacturing of materials used in these devices. The invention is especially related to the manufacturing method of at least one lithium-containing component of a lithium battery, a lithium-ion battery or a lithium-ion capacitor, which method utilises laser ablation i.e. material removal by means of laser light. The invention is further related to the use of the lithium-containing material produced by laser ablation deposition in batteries, capacitors, and other electrochemical devices.

### BACKGROUND OF THE INVENTION

As the need for mobile devices, electrically operated cars and energy storage grows, the need for the development of battery technology has increased. Li-ion batteries have been successful in very many applications, especially due to their good energy density and recharging possibilities compared, among others, to traditional Ni—Cd (Nickel-Cadmium) and Ni—Mn (Nickel-Manganese) batteries.

Today, the widely adapted lithium battery technology is based on a positive electrode (cathode) made from transition metal oxide and on a carbon-based negative electrode (anode). Migration pathway for the Li-ions between the positive and negative electrodes is the electrolyte which in the contemporary solutions is liquid but ways to use solid state electrolytes are being developed actively. Especially in the case of liquid electrolyte, a microporous polymer separator is used between the anode and cathode as an insulator which prevents the contact of the anode and cathode, but allows the passage of ions through the separator membrane.

The energy density of Li-ion batteries is defined by the capability of the electrode materials to reversibly store lithium as well as by the amount of lithium available for ion exchange in the battery. When a battery is being used, meaning energy is drawn from or stored in the battery, lithium ions move between the positive and negative electrodes. During usage, chemical and structural changes take place in the electrode materials which can affect the lithium storing capabilities of the materials or the amount of lithium. Part of the chemical reactions are irreversible and consume lithium which means there will be less lithium available for ion exchange, i.e, for storing and releasing stored energy. One example of this type of reactions is the formation of so-called SEI (Solid Electrolyte Interphase) layer on the surface of the negative electrode. Formation of the SEI layer takes place to a great extent during the first charge-discharge cycles, but it is also possible that new SEI layer is being formed continuously. In the contemporary Li-ion battery technologies, lithium is introduced into the cell structure almost entirely stored within the positive electrode material. When lithium is consumed in formation of the SEI layer during the first charge-discharge cycles, part of the materials in the electrodes won't be utilised and as inactive material increase the volume and mass of the battery thus reducing the energy density of the battery. It also known that Li has the tendency to get trapped in the material with which it forms a compound. This phenomenon can take place in the case when the active electrode material is a Li-compound forming material such as Si, Sn, or Al. Furthermore, the same phenomenon is known to happen with common current collector materials Cu, Ni, and Ti. Taking these into account and in order to optimise the performance of the Li-ion battery, it could be beneficial to fill the Li-storing material to its full capacity before normal use of the battery.

In order to compensate for the aforementioned lithium losses, excess lithium could be introduced in the cell structures before assembly of the battery such that after the first charge-discharge cycles the amount of available active lithium would be larger and would better fit the capacity of the electrode materials to store lithium. However, the total amount of lithium should be selected such that it doesn't exceed the lithium-storage capacity of the electrode materials during the use of the battery and thus wouldn't result in formation of metallic lithium on the surface of the negative electrode and wouldn't compromise the safe use of the battery.

Many methods have been developed for adding lithium into battery materials. This approach is called pre-lithiation. Pre-lithiation can be realised by chemical or electrochemical means, by using Li-metal or with help of additives. Large-scale and commercial exploitation of most of these approaches is limited by the lack of industrial and cost-effective methods. Especially, in many of the presented methods, pre-lithiation is realised as an separate process step before the assembly of the battery, which makes manufacturing process of the battery more complicated and slower. Pre-lithiated powder of electrode material can be utilised as such in the existing Li-ion battery manufacturing processes but, due to its instability, requires separate stabilisation step and/or a protective layer, which both reduce the total amount of active material ja can interfere with the normal operation of the battery. The methods and prior art are presented in publication by Florian Holtstiege et al.: “Pre-Lithiation Strategies for Rechargeable Energy Storage Technologies: Concepts, Promises and Challenges”, Batteries, Vol 4, 2018.

In some selected cases, pre-lithiation could enable the utilisation of novel materials in batteries thus improving the energy density and increasing lifetime of batteries. For example, using silicon as the active material in the negative electrode could be advantageous because, in theory, silicon has energy-storage capacity which is 10 times that of graphite, conventional active material in negative electrodes. Silicon has its limitations due to the volume changes induced by charging and discharging during usage of the battery which volume changes also cause damages in the structures, contacts between the particles and connections to other structures. In addition, the continuous volume changes of the silicon particles cause fractures in the SEI layers formed on the surface of the particles, which leads into formation of new SEI thus consuming available lithium during each charge-discharge cycle. By introducing silicon into the battery structure as lithium-comprising substance, it is possible to reduce the relative volume changes and the related re-growth of the SEI layers and mechanical damages in the electrode. Furthermore, pre-lithiation has the potential to improve the performance of the electrode material, e.g., by enabling the use of higher current densities thanks to reduced impedance and to improve beneficial mechanical properties which reduce the magnitude of stresses generated in the materials during the use of the battery.

When talking about lithium battery one usually means Li-metal battery which has metallic lithium as an anode. The advantage of Li anode is its high energy density, but their use is limited by the uncontrolled growth of so-called Li dendrites i.e., formation of needle-like projections, which can cause short-circuiting because dendrites are able to penetrate the separator membrane and electrically connect the anode and the cathode. This is a major safety risk. Also, lithium is highly reactive, which is why special arrangements in its handling and usage are required in order to avoid the harmful effects of the reaction products. For example, the reactivity easily results in formation of a thick SEI layer on the surface of lithium metal. Furthermore, when lithium metal is used as such, without a supporting framework as an anode, the volume change of the anode can be infinite because the anode does not contain lithium in the discharged state of the battery.

One of the limiting factors related to use of lithium metal is the difficulty to form reliable bonding to other materials. For example, bonding Li metal to the metal-foil current collector such that the contact withstands long-term usage has been found to be challenging.

Use of Li metal as an anode has been studied extensively, and solutions enabling safe use of Li metal have been developed. Possible solutions include producing a more robust SEI layer on the surface of Li, as well as protective coatings, solid-state electrolyte materials, and supporting frameworks. Lithium-storing framework should be chemically and mechanically stable, provide plenty of free surface area for storing lithium, be a good conductor of ions and electrons, and be light-weight.

Various protective coatings could be needed in order to minimise detrimental electrochemical and chemical reactions at the interfaces between different materials, especially those containing lithium, and to minimise the damages in the battery or capacitor materials taking place during the use. Also the protective coatings might need lithiation in order to function as Li-ion transporters. For example on the surface of the cathode, one could apply inorganic materials such as ZnO, Al₂O₃, AlPO₄, AlF₃, which in their lithium-containing form allow the passage of Li ions but prevent the reaction between the cathode and the electrolyte or prevent the dissolution of the components of the cathode. Solid-state electrolytes, such as Li_{2.88}PO_{3.73}N_{0.14} (LIPON), Li₁₀GeP₂S₁₂ (LGPS), Li_{9.54}Si_{1.74}P_{1.44}S_{11.7}Cl_{0.3}, Li_{9.6}P₃S₁₂ (LPS), Li_{1.3}Al_{0.3}Ti_{1.7} (LATP), LLTO, LLMO (M=Zr, Nb, Ta), can function as protective coatings for electrodes. Especially, the above-mentioned LLMO-type of electrolytes are applicable as mechanically durable protective coatings and supporting frameworks.

So-called supercapacitors are electrochemical devises used for storing energy. They are capable of taking in and producing higher currents than contemporary batteries and, in addition, they are able to withstand remarkably higher number of charge-discharge cycles. These properties complement the battery technology, for example, in electric vehicles where supercapacitors can be used for storing energy for short periods of time, taking in energy generated in braking and for providing the high currents required in accelerations. Li-ion capacitor is a particular hybrid type of supercapacitor which partially utilises the properties and functionalities of Li-ion battery technology. Controlling the amount of lithium and adding extra lithium in the structure of a Li-ion capacitor is a way to improve the performance of the capacitor, which is why pre-lithiation is already applied in commercial Li-ion capacitors.

In order to utilise Li metal, for example, in energy storage applications, one should be able to produce layers of Li metal which have especially the following properties:
Don't contain impurities or detrimental reaction products within the layer or on interfaces
Have a smooth surface
Have good adhesion to the substrate
Are controlled to contain a certain precise amount of Li metal

### SUMMARY OF THE INVENTION

The present invention discloses a method for producing lithium-containing materials and material layers applied in lithium batteries, Li-ion batteries and Li-ion capacitors where the method utilises the advantages of laser ablation deposition in controlling the composition and microstructure, doping of materials and producing multi-layer structures. The method is applicable for industrial mass production of material layers and coatings. The method enables both quantitatively and qualitatively precise processing of materials in controlled atmospheres, which makes it possible to produce the reaction sensitive materials such as lithium and lithium-containing compounds used in batteries and capacitors in the desired composition and without reaction products which could be detrimental to the operation of the end product.

With respect to the manufacturing method (laser ablation deposition, pulsed laser deposition, PLD) and the manufactured product (component of a Li-ion battery), the present invention relates to existing patent applications and granted patents which present the prior art:
Finnish patent application FI20175056 discusses manufacturing of anode materials and Finnish patent application FI20175057 discusses manufacturing of cathode materials by pulsed laser ablation deposition method. The applications disclose the utilisation of laser ablation deposition in the manufacturing of layered and composite structures as well as the possibility, enabled by the methods, to realise a performance-improving combination of electrochemical, chemical, and mechanical properties in the electrodes of a Li-ion battery. Additionally, these applications present mixing of electrode material with some other material by using a finished, mixed target material, separate targets or consecutive coating steps.
Finnish patent application FI20175058 discusses manufacturing of solid electrolyte materials by pulsed laser ablation deposition.
Finnish patent application FI20145837 (WO2016046452A1) discusses coating of porous polymer separator membranes used in Li batteries with porous material by applying pulsed laser ablation technique.
Finnish patent FI126659 (application WO2018087427) discusses producing a thin dense oxide coating on the surface of porous polymer separator membrane or electrode by pulsed laser ablation deposition.
Finnish patent FI126759B (application WO2016087718A1) discusses producing a porous coating by pulsed laser ablation deposition utilising composite target material.
Patent application US20050276931A1 discloses manufacturing of electrochemical device based on thin films (thickness e.g. <10 μm) and multi-layer structures by pulsed laser ablation deposition.

In addition, the goal of the present invention (producing a layer of lithium or adding lithium to, i.e. pre-lithiation of, component/components of an electrochemical energy storage device utilising lithium) has been discussed previously in the following patents, patent applications and publications which present the prior art:
Florian Holtstiege et al.: “Pre-Lithiation Strategies for Rechargeable Energy Storage Technologies: Concepts, Promises and Challenges”, Batteries, Vol 4, 2018.
Adding lithium to anode material of a silicon-based Li-ion battery by thermal evaporation has been discussed in publication Takezawa et al.: “Electrochemical Properties of a SiOx Film Anode Pre-lithiated by Evaporation of Metallic Li in Li-ion Batteries”, Chem. Lett., 46, 1365-1367, 2017.
The use of a three-dimensional supporting structure in a composite anode containing Li-metal has been presented in publication Zheng Liang et al.: “Composite lithium metal anode by melt infusion of lithium into a 3D conducting scaffold with lithiophilic coating”, PNAS, vol. 113, nr. 11, 2862-2867, 2016.
U.S. Pat. No. 9,966,598B2 “High capacity prelithiation reagents and lithium-rich anode materials”. The publication presents pre-lithiation reagent compound for batteries.
Publication KR101771122B1 presents a pre-lithiation method, which utilises silicon or silicon-oxide based lithium battery.
Other publications of the field are U.S. Pat. No. 9,705,154B2, WO2015192051A1 and US2017338480A1.
Patent KR101794625B1 shows coating with lithium by utilising molten Li-metal.
Patent application US2010120179A1 presents Li-ion battery anode in which lithium is added to the active anode material first after which the lithium-containing active anode material is ground into particles prior to producing the anode layer. Especially, the application shows the use of Si as such anode material. The application mentions laser ablation as one way to add lithium to the anode material.
Patent application US2019386315A1 present lithium electrode where the lithium is coated with a layer of aluminum oxide preventing direct contact of electrolyte and lithium metal and with a layer of carbon forming a stable interface with the electrolyte.
Patent application WO2005013397 discloses methods to introduce lithium into electrochemical systems and especially into electrodes used in such systems.
Patent application WO2018025036A1 discloses manufacturing of lithium metal coating by means of evaporation from a molten lithium source.
U.S. Ser. No. 10/476,065B2 discloses deposition of lithium coating on separator membrane. Among other manufacturing methods, the patent lists PVD (physical vapor deposition) as one possible way for producing the lithium layer. In addition, roll-to-roll manufacturing as well as deposition of protective layers and current-collector layers have been mentioned in the description of the patent.

In the method of the present invention a laser beam is directed to a target material removing material from the target as atoms, ions, particles or droplets or as combinations from this selection of species. The material ejected from the target is directed to the surface of the object to be coated resulting in a coating with the desired properties and thickness.

The quality, structure, quantity, size distribution, and energy of the material ejected from the target are controlled by the parameters used in laser ablation, these parameters comprise among others wavelength, power and intensity of the laser, temperature of the target, pressure of optional background gas, and, in the case of pulsed lasers, laser pulse energy, pulse length, pulse repetition rate and pulse overlap. Furthermore, the microstructure and composition of the applied target materials can be tuned together with the selected laser parameters in order to produce the desired process, material distribution and coating layer.

One significant advantage of laser ablation deposition is that it can be applied in processing of many different materials allowing for the production of different combinations of materials and microstructures. This provides freedom to realise the material selection and structures based mainly on the properties of the ideal end product and with less influence by the limitations of the manufacturing method. Depending on the material or combination of materials and the desired properties, the process parameters of laser ablation can be tuned in order to reach the desired microstructure and morphology.

By utilizing laser ablation one is able to produce both dense and porous coating layers and also to tune the porosity, particle size, and free surface area of the layer, all of which properties have significance in lithium batteries, Li-ion batteries, and Li-ion capacitors. For example, the porosity of the electrode layer enables distribution of the electrolyte within the whole volume of the electrode material, large contact area between the electrolyte and the particles of the electrode material, as well as short diffusion lengths of ions and electrons. Minimizing the particle size below 1 μm in porous structures has been recognised as a good approach to improve the functionality of lithium-storing materials. Large open surface area increases the contact area with the electrolyte thereby increasing the Li atom flux through the interface between the electrode particle and electrolyte. In addition, smaller particle size of the electrode material makes the required diffusion length of lithium smaller and increases speed of electron transfer. In some cases, small particle size and large specific surface area increase the Li-atom storage capacity by adding the number of storage sites of active Li atoms, which increases the specific storage capacity. The above-mentioned benefits achieved by controlling the structure of the electrode material have the capability to improve the overall performance of batteries.

When Li-ion battery is charged, Li ions travel in the electrolyte from the cathode to the anode and lithium is stored in the anode material, for example by intercalation between lattice planes in the case of graphite or by alloying in the case of silicon. During discharge, lithium moves as ions from anode to cathode and is stored into the cathode material, for example by intercalation between lattice planes in the case of LiCoO₂. The storage of lithium causes changes of structure and properties of the electrode materials. Especially for the lithium-alloying electrode materials, the volume increases significantly when alloyed by lithium, for example up to 4 times its initial volume in the case of silicon and over 2 times its initial volume in the case of tin.

Controlling and reducing the size of the subunits of the structure by laser ablation improves the durability of materials against fractures and breaking of bonds resulting from the volume changes caused by the charge-discharge cycles. Smaller dimensions of the microstructural units, such as the anode material particles, are able to better accommodate the stresses related to volume changes whether the units were particles or fibrous pieces or a combination of the two. For example, when using silicon as anode material, decreasing the size of particles below 150 nm reduces the tendency of crystalline silicon to crack and the risks for deteriorating the battery performance. By selecting suitable laser parameters and controlling the deposition temperature, laser ablation technique allows for producing silicon particles in amorphous phase, which reduces the tendency for cracking during charge-discharge cycles and increases crack-free particle size even up to 1 μm.

Also, the empty volume (porosity) generated within the structure during manufacturing increases the possibilities to accommodate to structural volume changes taking place especially during the use of the battery. In addition to total amount of porosity, it is essential to control the distribution of porosity. Especially, it would be advantageous to improve the uniformity of the porosity distribution. For example, when silicon-doped anode material is produced with binder materials by slurry method, the porosity distribution in the produced coating layer is not uniform in terms of volume and size distribution of the pores, which may cause high local stresses and microscopic cracking. Laser ablation deposition enables structures with uniform pore distribution, which type of structures can better withstand the volume changes and the resulting stresses related to the charge-discharge cycles without breaking.

A reaction layer called solid electrolyte interphase (SEI) is formed on the surface of anode materials during the use of Li-ion batteries especially when based on liquid electrolyte. This reaction layer easily breaks because of the volume changes of the anode material, which breaking exposes fresh anode material surface to react with the electrolyte. This leads to continuous formation of new reaction layer and increase of thickness of the layer and thereby consumption of the electrolyte. Furthermore, the increased thickness of the reaction layer interferes with the diffusion of Li-ions thereby deteriorating the performance of the Li-ion battery. The cracks generated in the reaction layer may also contribute to the growth of needle-like Li dendrites through the separator membrane causing a short circuit and permanent damage to the battery. Reducing the particle size lowers the risks of cracking of the reaction layer and of formation of an unstable reaction layer.

Use of some promising electrode materials, such as anode material Li₄Ti₅O₁₂, is limited by poor electron conductivity which could be improved not only by reducing the particle size of Li₄Ti₅O₁₂ but also by adding metal particles, such as nickel or copper, to the particles and into the structure in the coating process. This can be realised in laser ablation technique either by adding a desired amount of the mentioned doping materials in the target material or by doing so-called combinatorial coating, for example such that together with the ablation of Li₄Ti₅O₁₂, material flow of copper (or some other material able to improve electrical conductivity) produced by laser ablation is directed simultaneously to the coating. One possibility is to produce the coating in layer-by-layer manner, for example such that after producing coating layer of electrode material, a coating layer of material improving the conductivity is produced followed by a layer of electrode material, and these sequences are repeated long enough to produce the desired structure and total layer thickness.

In addition to the particle size in the electrode coating, one has to take into account that related to the specific capacity one might need to optimise the particle size, not necessarily to minimise it. For example, in the case of Li₄Ti₅O₁₂, particle size of <20 nm might decrease the specific capacity, and actually it would be beneficial to control the particle size within the range 20-80 nm. Also, the amount of storage sites of Li atoms in very small particles could be smaller due to the higher surface-area-to-volume ratio, emphasizing the need for optimising the structure. In the conventional manufacturing processes of Li₄Ti₅O₁₂, the particle sizes are more than 1 μm, i.e., not within the optimal size range.

In laser ablation deposition process, to improve the performance of the battery, it is possible to tune the particle size into the optimal range by controlling laser parameters and background gas pressure, which is a significant advantage when compared to, for example, slurry coating or other physical or chemical deposition methods, such as atomic layer deposition (ALD) or chemical vapor deposition (CVD).

If deemed necessary, as a final coating process step after producing so-called active electrode material coating layer, it is possible to produce a thermomechanical protective layer, a coating influencing the properties of the reaction layer, or a coating layer improving the chemical durability of the electrode material layer. The porosity and thickness of this final coating layer can be adjusted based on the required functionality.

By producing a composite material structure either by means of layer-by-layer process or by means of combinatorial process (combining two or more simultaneous material flows produced by laser ablation) one is able to modify the properties of an electrode material coating layer in many different ways. For example, when together or sequentially layer-by-layer with silicon particles or fibers another material with suitable properties, such as carbon, is ablated, one is able to improve the mechanical flexibility and transformation capability of the structure when compared to the case where the material contains only silicon. When different materials are added in suitable ratio and size distribution by means of laser ablation, either combinatorially or in layer-by-layer fashion, one is able to reach optimal combination of electrochemical, chemical, and mechanical properties.

The crystallinity of the material produced by laser ablation can be controlled, for example, by adjusting the temperature of the substrate. Performing pulsed laser ablation using short pulses allows for generating an amorphous structure which, for example, has different lithium diffusion properties when compared to crystalline structure in the case of silicon. For example, the diffusion of lithium into silicon particles is more linear, which reduces the cracking of the particles.

As a general remark, one can conclude that laser ablation gives rise to features which cannot be produced by other means in the end product. Especially the adhesion of a material layer produced by laser ablation deposition to the substrate is very good regardless of the materials, which is not always possible with other coating methods. Furthermore, the purity of the coating and precision of the selected material distribution are outstanding.

Laser ablation can be utilised to produce many of the advantageous features described above based on this one process technology, even in single coating process step with certain prerequisite conditions. Alternatively, laser ablation process can also be realised in several sequences in a process line where, for example, porous layer formed of electrode material particles is produced in the first phase and layer of lithium is produced in the next phase. These phases can be performed sequentially until the desired coating layer thickness has been produced. The process can also be supplemented with a phase where doping with some other metal layer or dispersion is performed. Furthermore, in order to prevent detrimental reactions at the interfaces between different materials, protective layers can be deposited between layers in separate process sequences. Because the coating process takes place within a vacuum chamber inside which the gas pressure and composition can be controlled, one is able to minimise detrimental reactions. This ability is essential when handling battery materials and reaction sensitive lithium especially.

When the aim is to manufacture a composite or an alloyed material, for example a combination of lithium and silicon, one can direct material flows from two different targets simultaneously towards the object to be coated, in other words, using the so-called combinatorial method as described previously. When necessary, the parameters of the lasers directed to the different targets can be adjusted individually and independently in order to optimise the ablation processes of the different target materials and in order to generate the desired structure, compostions, and material distribution. This type of structure and alloying by lithium could enable the use of, inter alia, silicon and tin as anode materials with less cracking caused by volume changes.

To reduce the particle size of an electrode material and to generate the beneficial features described previously, one can also use methods where nanoparticles are manufactured first, for example, by chemical means. As a next step the nanoparticles are mixed with binder materials and other components (for example lithium and carbon) which form the electrode material together with the nanoparticles, and the final electrode material layer is manufactured using this mixture, for example, by slurry methods. However, handling of nanoparticles is very complicated, and the described way of using nanoparticles requires several processing steps, which increases the throughput time, expenses, and probability for quality issues. In the method of the present invention, the production of nanoparticles, the coating process, and adding and mixing of other materials take place in one single or two sequences of the laser ablation process, which improves the cost-efficiency and controllability of the process. Furthermore, there is no need for the complicated handling of nanoparticles. Because binder materials are not required, as opposed to slurry methods for example, the potential dissolution of the binder won't interfere with the electrochemical operation of the Li-ion battery.

In principle, it is possible to use some or several of the previously described methods in combination with some other coating method, for example, as sequential process steps such that laser ablation is utilised in the coating process step where it suits the best and some or several other coatings methods are utilised to supplement laser ablation.

This can be realised as consecutive process steps or as separate processes. Additionally, one needs to take into account, that different parameters can be used for generating different types of laser ablation processes, combining of which processes to simultaneous events or to sequential phases can create both quality-related and productional characteristics or benefits.

The coating process can be realised as roll-to-roll method or, for example, for sheets which are fed to the process line as successive sheets.

Considering productivity of high-volume products, it is essential to perform the deposition process by utilising a wide laser-beam (scan line) array which can be generated, for example, by moving or rotating mirrors. The laser beam scan line ablates material from the target in the desired way and across the whole coating width, and the material flow is directed from the target onto the selected area on the surface of the substrate. The productivity can be increased also by using several laser sources and laser beams to ablate material simultaneously from one or several targets.

The inventive idea of the invention also comprises the final product manufactured using the method, i.e. a Li battery, a Li-ion battery, or a Li-ion capacitor, comprising all the required material layers, of which at least one layer containing lithium metal or lithium compound is manufactured by laser ablation deposition.

### SHORT DESCRIPTION OF THE DRAWINGS

FIG. 1 illustrates the principle of the coating procedure with different physical components in an example of the invention,

FIG. 2 illustrates the principle of forming a fan-shaped array of parallel laser beams with an equipment setup of the invention,

FIG. 3 illustrates an example of the so-called roll-to-roll principle related to the coating process,

FIG. 4a illustrates producing a coating material on a substrate by PLD method,

FIG. 4b illustrates an arrangement for producing a porous coating layer,

FIG. 4c illustrates an arrangement for producing a composite-structured coating layer by using a composite-structured target,

FIG. 4d illustrates an arrangement for producing an alloyed-material coating layer by using a composite-structured target,

FIG. 5 illustrates a typical structure of a Li-ion battery as a cross-section image,

FIG. 6 illustrates the use of consecutive processing units in roll-to-roll manufacturing related to the method of the invention,

FIG. 7a illustrates a combinatorial coating method for composite coating layer (including also mixed coating) by using two simultaneous material flows,

FIG. 7b illustrates a combinatorial coating method for alloyed-material coating layer by using two simultaneous material flows,

FIG. 8a illustrates the use of consecutive coating units for improving productivity,

FIG. 8b illustrates the use of consecutive coating units for improving productivity when manufacturing composite structures,

FIG. 8c illustrates the use of consecutive coating units for improving productivity when manufacturing mixed materials.

### DETAILED DESCRIPTION OF THE INVENTION

In the method of the invention, a lithium-containing material layer or a multi-layer structure of a lithium battery, Li-ion battery, or Li-ion capacitor is produced by laser ablation deposition which is utilised for producing material layers which are suited for laser ablation deposition or which gain relative productivity or quality advantages because of the method.

In laser ablation material is ejected from a solid or liquid surface by directing on it a laser beam with high enough irradiance. The laser beam can be pulsed or continuous wave. In suitable environmental conditions, the material removed by laser ablation can be collected on the surface of a substrate and this way form a coating layer. This kind of method is called laser ablation deposition.

In pulsed laser ablation utilising a pulsed laser beam, material is removed by short laser pulses duration of which can vary within the range from milliseconds down to femtoseconds. Pulsed laser (ablation) deposition (PLD) typically involves laser pulses with durations of 100 000 ps at most (in other words 100 ns at most). In one embodiment, it is also possible to use ultrashort pulsed laser ablation deposition (so-called US PLD) method where the duration of laser pulses is 1000 ps at most. When deemed necessary, different laser parameters are used for producing the different material layers of a lithium battery, a Li-ion battery, or a Li-ion capacitor.

When the removal of materials and generating the material flow from a target or several targets to the surface of the object to be coated is performed by using laser pulses, the laser fluence (J/cm²) needs to be high enough in order to remove material from the target. The threshold fluence, known as ablation threshold, at which the material removal from the target initiates, is a material specific parameter value of which also depends, inter alia, on the laser wavelength and duration of laser pulses.

The typically used and available laser energies have magnitude which requires the laser beam to be modified optically such that the area of the laser spot on the target surface is made smaller in order to reach high enough fluence. The simplest way to realise this is to place a focusing lens in the laser beam path at a suitable distance from the target. However, one needs to take into account that the laser beam intensity has characteristic spatial and temporal distributions which depend on the laser and the optics used. In practice, neither the intensity, nor the fluence for that matter, has a perfectly homogeneous distribution within the laser spot on the target surface even if means for homogenising the distribution were used. This can result in a situation where the ablation threshold is exceeded only in certain parts of the laser spot, and the size and proportion of the area exceeding the ablation threshold depend on the total laser energy being used.

Removal of material can take place in the form of atoms, ions, molten particulates, exfoliated particles, particles condensed from atoms and ions after ejection, or combinations of the some of the above. The mode of removal of the material and behavior of the material after removal from the target, such as the tendency to condensation, depend, inter alia, on how much the laser energy exceeds the ablation threshold. Depending on the material and on the requirements set for the structure material and morphology of the coating layer, the parameters of laser ablation can be adjusted. Suitable parameters can be defined specifically for each material to produce desired coating layer.

A characteristic feature of laser ablation is that the ablation process generates electromagnetic radiation, properties of which depend on the material being processed by laser ablation as well as on the laser parameters used for the ablation and, in some cases, also on the properties of the ablation environment. By analysing the spectrum of this electromagnetic radiation generated by the ablation one can collect essential information from the ablation process and this information can be used for controlling the process. For example, this enables stabilisation of the process for a long-duration coating process such that the desired properties of the coating layer can be maintained from the beginning to the end and the product can be manufactured in homogeneous quality. One needs to be able to monitor the process in such detail and, when necessary, to adjust the process, because, for example, the target wears continuously due to ablation and the properties of the laser beam hitting the target can change in addition. The spectrum of the electromagnetic radiation generated by laser ablation is a kind of a fingerprint of the process, which also allows for repeating the process. The spectrum also allows for recognising the elements and potential impurities in the target material.

For reliability of the measurement of the spectrum generated by the laser ablation it is important that the measurement can be reproduced reliably. Because of the above, the setup of the equipment collecting the electromagnetic radiation needs to be arranged such that the passage of the radiation between the point of ablation and the measuring device is unobstructed and constant. Because material ejected by laser ablation can be accumulated to any surface with line-of-sight to the point of ablation, the measuring device and related optics for collecting the electromagnetic radiation need to be protected. Means of protection could be, for example, a movable window or plastic membrane which allow for continuously exposing fresh surface to the radiation path in order to enable unobstructed passage of the radiation from the point of ablation to the collecting optics. As an alternative for this type of consumable protector, continuous cleaning of the window or membrane by ion bombardment or laser ablation could be performed for example. In addition, the reliability of the measurement can be improved by using a reference radiation source which allows for calibration of the measurement and for direct comparison of the spectrum of the reference to spectrum generated by the ablation.

In addition to a constant repetition rate of laser pulses, laser pulses can be delivered to the target as so-called bursts which are composed of a selected number of pulses at selected repetition rate. For example, 100 W of average laser power can be produced by individual 100-μJ laser pulses at 1-MHz repetition rate or by bursts composed of 10 pieces of 10-μJ laser pulses at 60-MHz repetition rate and with 1-MHz burst repetition rate. It is also possible to control the pulse energy of individual pulses composing the burst.

Bursts, or laser-pulse packages, and the high pulse repetition rates enabled by bursts are significant especially in the case of short laser pulses. By using bursts one is able to change the interaction of the laser with the material and to control the properties of the ejected material. For example, the high repetition rates enable increasing the total energy of the material ejected from the target and reducing the amount or the size of particles in the ejected material, because part of the laser pulses interact directly with the cloud of ejected material instead of the solid surface of the target.

It is essential to notice that, after ejected from the target, changes in the structure, size distribution, and composition of the material can take place in the material flow before the material attaches to the substrate. This process of changes can be controlled, for example, by the atmosphere within the deposition chamber, i.e., the composition and pressure of the background gas, as well as by adjusting the travel distance of the material (from the target to the substrate).

Additional energy can be brought to the material flow also by directing another laser beam to it. Also, by means of a continuous wave laser beam, above-mentioned burst of laser pulses, or high repetition rate one is able to make part of the laser energy absorb to the ejected material. Laser beam directed to the material flow can be used for making potential particles in the material flow smaller and also for increasing the total energy and degree ionisation.

Several laser beams directed to one and the same target can be used simultaneously in laser ablation. Especially when separate laser beams have different properties, the simultaneous interaction on the same area on the surface of the target changes the ablation process. For example, a continuous wave laser beam can be used for warming up or for melting an area, and a pulsed laser beam directed to that same area absorbs and removes material more efficiently. Combining different wavelengths of laser beams and different durations of laser pulses enables, in addition to making the process more efficient, controlling the material quality, such as reducing the amount of particles and increasing the density of the coating layer, when the laser spots at least partly overlap and interact simultaneously on the surface of the target.

The composition of the material can be changed by using reactive background gas (for example, oxygen for oxides and nitrogen for nitrides) or by bringing together material flows from several different sources. By realising ablation process simultaneously on several different targets and directing the material flows into the same volume it is possible to form compound-material coatings, composition of which can be adjusted flexibly on element level. A special case of this kind of arrangement is a composite target which has been produced, for example, by mixing two materials in powder form and compacting them into a solid piece. When a laser beam with high enough irradiance is directed to a target composed of two materials, ablation affects both materials as if there were two separate material sources, and material flows generated from these sources are able to interact and react with each other to form a new compound which condenses on the substrate to form a coating. Laser ablation deposition can be used in the above-mentioned compound-forming approach also in combination with other coating methods, in which case the other material flows can be generated by thermal evaporation, sputtering by ions, or electron beam.

During or after completion of the coating process, the crystal structure and adhesion (between the coating and substrate) of the produced coating can be affected by heating the substrate or by directing ion bombardment, laser beam, light pulses, or laser pulses on the coating layer.

Laser ablation deposition is utilised in controlling micro- and nanostructures in order to achieve and optimise functional benefits in lithium batteries, Li-ion batteries, and Li-ion capacitors. Nanostructured electrodes have high surface-area-to-volume ratio, owing to which they are capable of producing high energy and power densities in electrochemical energy storage applications. Small particle size of the electrode material speeds up the storaging and release processes of lithium and lithium ions because it makes shorter the (diffusion) distance the lithium ion needs to travel inside the particle. On the other hand, when the amount of active surface area per unit volume increases, the number of reactions between electrode surface and electrolyte increases leading, for example, to growth of total amount of SEI layer resulting to the decrease of the amount of active lithium. In the case of nanostructured electrodes, adding lithium to the structure thus has a great relevance in compensating the side effects caused by the nanostructure. Small particle size and electrically conductive coatings and doping agents are means for improving the electron and ionic conductivity of electrode materials.

When incorporating lithium into the structure of a battery material, one needs to optimise especially the total amount of active lithium with respect to the storage capacity of the electrodes of the Li-ion battery and, at the same time, to take into account the amount of lithium consumed in the irreversible reactions during the first charge-discharge cycles. This way, one can maximise the utilisation of the active electrode materials and increase the energy density of the battery. In addition, the selection of materials and structures allows for optimising the ionic and electron conductivities as well as for preserving the properties and performance of the battery in the long run and as the number of charge-discharge cycles increases. One needs to take into account also the manufacturing costs which are affected by selection of raw materials as well as by battery safety.

Suitable materials to be used as anode materials in Li-ion batteries are, for example carbon in different morphologies (carbon particles, carbon nanotubes, graphene, graphite), titanium comprising oxides such as Li₄Ti₅O₁₂, TiO₂, silicon lithium-silicon alloys, tin, germanium, silicon oxides SiOₓ, SnO₂, iron oxides, cobalt oxides, metal phosphides, and metal sulphides. Also other applicable materials and compounds, alloys, composites, or layered structures based on the materials can be utilised. For example, possible applicable silicon compounds and alloys are Si—Sn, SiSnFe, SiSnAl, SiFeCo, SiB₄, SiB₆, Mg₂Si, Ni₂Si, TiSi₂, MoSi₂, CoSi₂, NiSi₂, CaSi₂, CrSi₂, Cu₅Si, FeSi₂, MnSi₂, NbSi₂, TaSi, VSi₂, WSi₂, ZnSi₂, SiC, Si₃N₄, Si₂N₂O, SiOₓ, LiSi, LiSiO.

Lithium batteries can use Li metal as anode. It could be beneficial for the functionality of the battery that the Li-metal electrode structure has three-dimensional supporting structure which prevents large volume changes of the electrode and reduces the growth of Li dendrites. The supporting structure can include electron-conducting material, such as carbon or inert metal which reacts as little as possible with Li metal, and/or Li-ion-conducting material, such as solid-state electrolyte material. Especially LLMO (where M=Zr, Nb, Ta) type of solid-state electrolyte materials are applicable to be used as such structure.

The cathode can be any cathode material applicable to be used in a Li-ion battery, materials such as lithium-comprising transition-metal oxides such as LiCoO₂, LiMnO₂, LiMn₂O₄, LiMnO₃, LiMn₂O₃, LiMn₂₋ₓMₓO₂ (M=Co, Ni, Fe, Cr, Zn, Ta, 0.01<x<0.1), LiNiO₂, LiNi₁₋ₓMₓO₂ (M=Co, Ni, Fe, Mg, B, Ga, 0.01<x<0.3), LiNiₓMn₂₋ₓO₄ (0.01<x<0.6), LiNiMnCoO₂, LiNiCoAlO₂, Li₂CuO₂; LiV₃O₈, LiV₃O₄, V₂O₅, Cu₂V₂O₇, Li₂Mn₃MO₈ (M=Fe, Co, Ni, Cu, Zn), various materials capable of storing lithium-ions within their structures (so-called intercalation cathode materials) such as TiS₃ ja NbSe₃ ja LiTiS₂, or some polyanion compound such as LiFePO₄. Other cathode materials are sulfur and materials based-on sulfur composites or sulfur: Li₂S, transition-metal sulfides MS₂ tai MS (M=Fe, Mo, Co, Ti, . . . ). Also other applicable materials and compounds, alloys, composites, or layered structures based on the materials can be utilised.

Doping of the electrode materials with a small amount of suitable material is possible by adding, for example, particles of nickel, silver, copper, or platinum on the surface of the material as a dispersion. The goal of using combined materials, i.e. composite materials or doping or mixtures is to remove weaknesses related to certain electrode materials, these weaknesses comprising, for example, weak ionic or electrical conductivity or microscopic damages caused by volume changes. The desired advantages and the optimisation of the desired microstructure varies by the material and application, because all groups of materials have, in addition to their strengths, their weaknesses which one wants to minimise with the help of the coating method based on laser ablation.

When the goal is to produce porous materials, their manufacturing can be realised based on quite diverse ablation processes and combinations of ablation processes. The selection of ablation process is affected by the desired porosity, particle size and thereby the open surface area, thickness of the coating layer (the particle sizes vary depending on the ablation mechanism), degree of crystallinity of the coating layer, productivity requirement, and requirements related to control of the stoichiometry. With single-element materials, there will be no problems regarding stoichiometry unless the material reacts with the atmosphere inside the deposition chamber. In the case of multi-element compounds, controlling stoichiometry needs to be taken into account, because change in the composition may also cause changes in the structure and functionality of the material. For robustness of the porous structure, it is critical to produce a structure such that the material flow constitutes, in addition to particles, fine, atomised or ionised material to help bonding between particles and thereby to contribute to robustness of the structure. Moreover, sufficient kinetic energy of the material flow helps bonding particles together and to the substrate.

The coating method based on laser ablation differs from other thin-film deposition methods in that laser ablation deposition allows for controlling relatively accurately the size of the particles which form the coating layer. If the desired coating layer is going to be produced by generating first a substantially atomised or ionised material, the tendency of the material to form so-called clusters depends particularly on the speed and size distribution of the units composing the material flow generated by ablation and on the pressure of the background gas. For example, the condensation of a specific material flow generated from a target by laser ablation into particles can be enhanced by increasing the pressure of the background gas in the deposition chamber in a controlled way. Increase of the pressure increases the possibility of collisions to gas atoms and molecules. In these collisions, the units of the material flow lose energy and change their direction. Deceleration and changes of direction, for one, increase the possibility to collisions between units of the material flow and thereby the possibility to form clusters.

To produce a porous material, it is also possible to perform the ablation process such that particles are ejected from the target by exfoliating (chipping) material from the surface of a target manufactured from powdered material. The exfoliation (chipping) and boundaries where the cracking takes place can be adjusted, for example, by weakening selected microstructural areas and interfaces, such that the material can be ejected easier and as pieces of certain size. Alternatively, the laser ablation process can be adjusted such that the surface of the target melts locally, and molten droplets are ejected from the target and directed to the surface of the substrate material. In the aforementioned case, the process can be defined as thermal ablation. The alternative methods described previously can be selected according to the desired microstructure of the material to be produced and which ablation process best suits the material.

Laser ablation process enables different material and coating concepts to be produced even with one single method and equipment owing to the flexibility of the method and its applicability to different materials by selection of suitable parameters. This considerably reduces the required equipment-related investments for battery material coating solutions, increases the speed of manufacturing, and reduces the amount of errors in manufacturing and handling.

The method is applicable particularly in roll-to-roll manufacturing, where the substrate (for example copper foil) is guided from a roll to the coating stations as a continuous web, after which the battery material coating is deposited on the web in the coating stations (there can be one or more units). The coating stations can be setup in a row also in such a way that either the same material or different materials are deposited in several coating stations consecutively increasing the productivity or in such a way that different materials are deposited in the coating stations to produce composite or multi-layer structures or to add dopant materials, for example materials improving electrical conductivity, on the surfaces of battery materials. These application alternatives have their own exemplary drawings presented. The coating stations can be separate units, which enables controlling the properties and environment, in terms of for example gas, pressure, and temperature, of each coating station individually and applying the most suitable circumstances for each process.

Instead of several coating stations in a row, the coating can be manufactured in roll-to-roll process such that the web to be coated first passes through the coating station, and a layer of the desired material is deposited on the web. As a next step, the movement direction of the web is reversed and the target material is changed in the coating station automatically, and deposition of another material is performed, the material being for example a dopant material (mixture material), second part of a composite material, second layer material of a layered material, and this process is repeated until the desired structure is complete. It is also a possibility, that the different steps of deposition and handling are performed in separate processing units, and a full roll is completed in one processing unit and transferred to the next unit under suitable conditions, and this procedure is repeated until the desired level of completeness has been reached.

The coating stations enable also production of different types of protective layers on the surfaces of different layers or, for example, only on the final layer of battery materials in order to, for example, prevent the dissolution of essential components of the material or the detrimental reactions with the environment or with the electrolyte.

It is not necessary to use laser ablation for the deposition of all the material layers, and other deposition and manufacturing methods of material layers as well as various handling and conditioning methods can be included in the processing chain if that is optimal from the overall approach point of view. Such supporting deposition and manufacturing methods include CVD (Chemical Vapor Deposition) technology, ALD (Atomic Layer Deposition) technology, and PVD (Physical Vapor Deposition) technology such as sputtering. Handling and conditioning methods of materials comprise, inter alia, various heat treatments (ovens, lamps, laser) as well as surface modifications and texturing (ion bombardment, laser ablation). For example, the good adhesion to the substrate, which is characteristic to laser ablation deposition, can be utilised by producing only a thin layer of the desired material on the surface of the substrate first by laser ablation deposition, after which the deposition process is continued with another suitable method.

The composition of the material detached by laser ablation must be preserved within appropriate range for the functionality of the coating. In principle the pulsed laser technology, especially ultrashort pulsed laser technology is a suitable method for minimising disadvantageous changes of composition, for example, due to different type of evaporation or the non-simultaneous evaporation of doping substances. By means of the ultrashort pulsed laser technology it is possible to minimise the melting of the material and the formation of extensive molten areas, which increase uneven material losses and impede the control of stoichiometry. In case of many target materials, restricting the duration of the laser pulses to under 5-10 ps is sufficient to minimise the melting of the target and excessive loss of doping components in laser ablation if the overlapping of laser beams is minimal. At high repetition rates, the overlapping of laser pulses may cause the material to melt even if short pulse durations were used. A change in stoichiometry may cause a loss of the desired structure and appropriate functionality. In industrial manufacturing, the process must stay constantly stable, due to which also changes occurring in the target composition or other properties over long periods of time are detrimental.

When manufacturing composite materials, layered structures or by doping the principal material of the coating with some other material, the optimum process parameters and circumstances of different materials are not necessarily the same. This must be taken into account when planning and combining different steps in the production process. If it is desired to manufacture a composite material using a combinatory solution, the laser parameters can be tailored optimally for different materials by using a different laser source for different materials, but in this case, it must be possible to ablate all materials sufficiently well in the same coating atmosphere, because it can be difficult to adjust the coating atmosphere separately when performing combinatory ablation. If it is necessary to adjust the coating atmosphere separately for all materials, this can be most easily carried out in successive coating steps so that a coating atmosphere advantageous for different materials can be controlled separately. Several such coating steps can be built in a process solution depending on the type of material distribution one desires to produce.

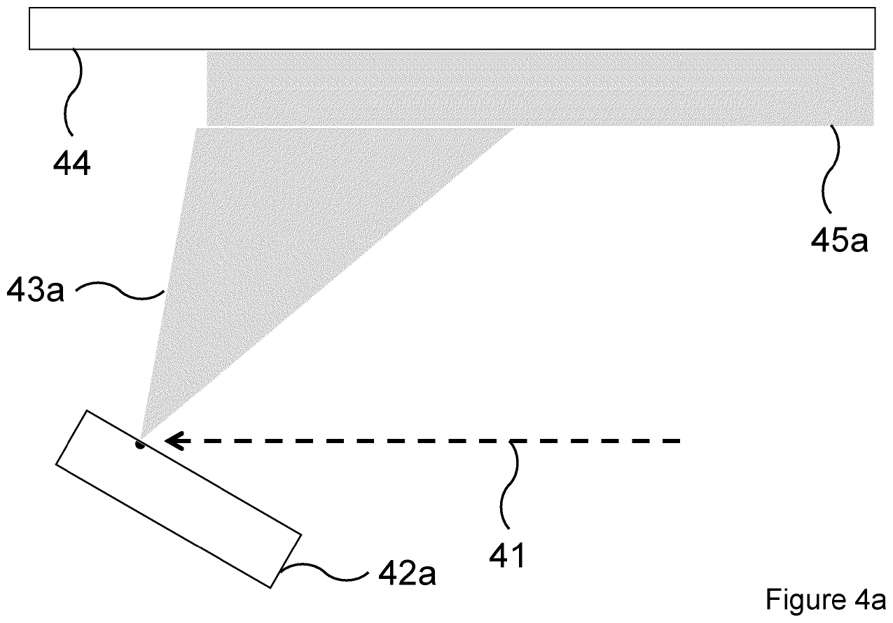

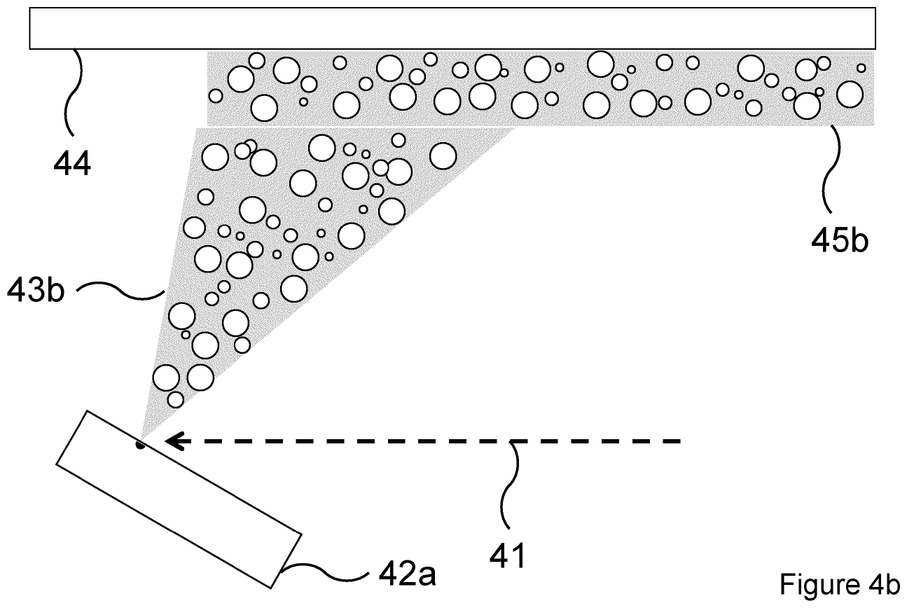

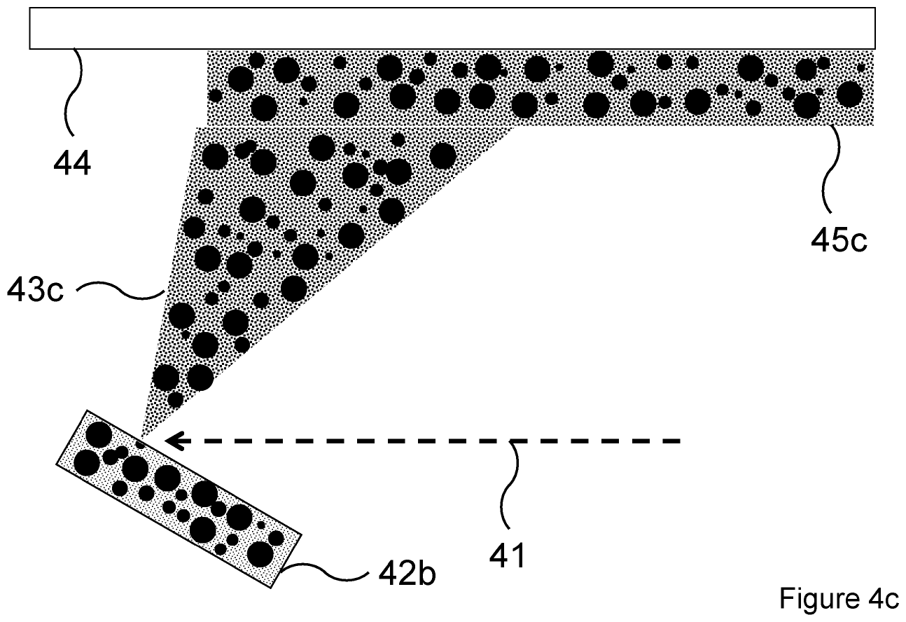

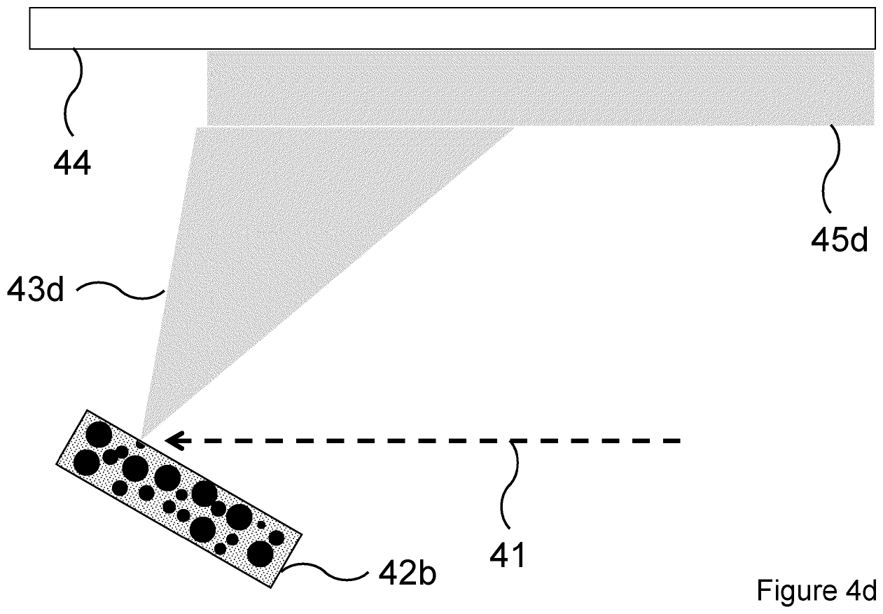

In certain situations, it is also possible to make the desired doping to an individual target material piece, and if the ablation thresholds of the materials in relation to each other and the condensation tendency in the chosen gas atmosphere are suitable, the composite structures can be manufactured by mixing the desired materials to the target material in a desired proportion. This situation is separately illustrated in FIG. 4c.

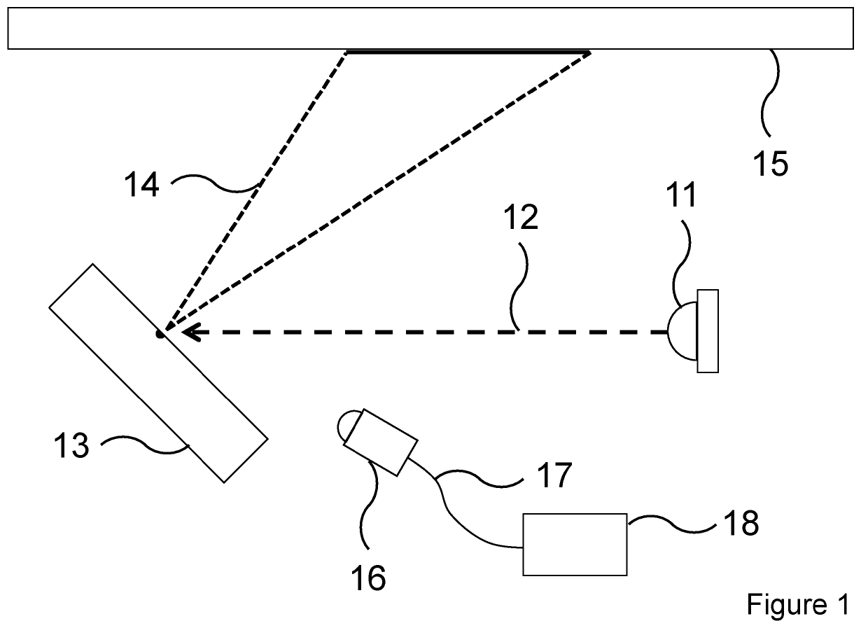

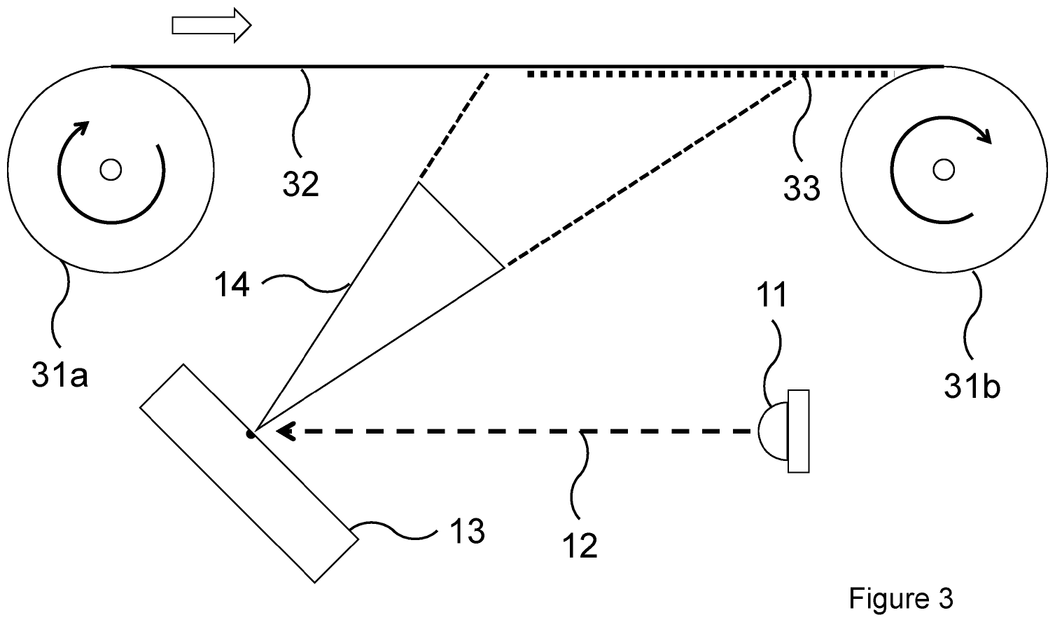

The basic principle of the method (laser ablation deposition) is illustrated in the view of principle in FIG. 1, in which the structural parts and directions of motion of the material included in the coating process are shown at a principled level. In FIG. 1, the energy source for the ablation process is the laser light source 11, from which laser light is directed as a beam 12 towards the target 13. The laser beam 12 causes local detachment of material on the surface of the target 13 as particles or other respective fragments, which have been mentioned above. Thus, the material flow 14 is generated, which extends towards the object 15 to be coated. The object 15 to be coated can also be called a coating base or substrate. The correct alignment can be performed by setting the direction of the plane of the target surface 13 appropriately in relation to the object 15 to be coated so that the direction of the kinetic energy of material flow is towards the object 15 to be coated. The laser source 11 can be moved in relation to the target 13, or the target 13 in relation to the laser source 11, and the angle of the laser beams in relation to the surface of the target 13 can be varied. Optical components such as, for example, mirrors and lenses can be placed between the laser source 11 and the target 13. Furthermore, a separate optical arrangement can be placed between the laser source 11 and the target 13 for focusing and parallelising the array of laser beams hitting the target 13. There is a separate FIG. 3 of this arrangement.

The electromagnetic radiation generated in laser ablation can be collected by using the arrangement shown in FIG. 1, in which arrangement the radiation-collecting optics 16 has been positioned such that it has an unobstructed view to the material released by ablation. Between the collecting optics 16 and releasing material, it is necessary to place protective and movable window such that material is not able to accumulate on the surface of the collecting optics 16 and attenuate the radiation to be measured. From the collecting optics 16, the electromagnetic radiation is guided within an optical fiber 17 to a spectrometer 18. With the spectrometer 18 and a computer connected to it one is able to measure the spectrum of the electromagnetic radiation generated in the laser ablation and to interpret the meaningful information which is used for adjusting the parameters of the laser ablation process such that the desired coating can be realised on the surface of the object 15 to be coated.

The material flow 14 in FIG. 1 can be fan-shaped so that a wider area can be coated on the area of the surface of the object 15 to be coated by one angle of orientation of the target 13 assuming that the material to be coated is not transferred laterally (seen from the figure). In another embodiment, the material to be coated is movable, and of this embodiment there is the separate FIG. 3.

Generally, in an example of ablation used in the invention, the detachment of the target surface material, formation of particles, and transfer of material from the target to the substrate and to the previously formed material layer are achieved with laser pulses directed on the target, in which the duration of an individual laser pulse can be in the range 0.1-10000 ps.

In an example of the invention, laser pulses can be generated at a repetition rate which is between 50 kHz-100 MHz.

The coating layer formed by the material detached by laser ablation and transferred as particles from the target to the substrate must build reliable bonding to the substrate or previously prepared material layer. This can be achieved by sufficient kinetic energy of the particles, which provides sufficient energy for generating bonds between different materials. In addition, in a particle-intensive material flow, it would be preferable to have a sufficient quantity of atomised and ionised material to support the generation of bonds between the particles.

A very essential process parameter in laser ablation when manufacturing porous coatings is the gas pressure used in the process chamber. Increasing the gas pressure promotes the formation and growth of particles during the material's flight from the target to the surface of the material to be coated. An optimal gas pressure may vary according to the gas or mixture of gases being used, to the type of material being coated and to the desired particle size distribution, porosity and adhesion between the particles, and the bond of the particles to the rest of the material. For the selection and purity of the gas, one needs to take into account the potential reactions with the materials of the substrate, of the object to be coated, and of the target.

In an embodiment, the laser ablation and deposition take place in a vacuum chamber, i.e. either in a vacuum or background gas, where a controlled pressure can be applied. A possible alternative is to set the pressure between 10⁻⁸-1000 mbar. When pursuing porous coatings or an increase in porosity, a background gas pressure of 10⁻⁶-1 mbar is typically used. The relative purpose of background gas varies depending on the density and total energy of the material flow and on the distance the material travels from the ablation point to the surface of the object to be coated. If laser ablation is performed with so-called thermal ablation and local melting of the target material surface, a porous coating and a particle size of less than 1 μm can also be produced in a low background pressure, because the formation of particles occurs through molten drops and not through condensation from atomised material. Further, a particle-based material flow can be achieved also by promoting the detachment of particles in the target material through selective energy absorption or partial cracking of target materials.

Controlling the composition and pressure of the gas inside the deposition chamber has significance especially when reaction sensitive materials, such as lithium, are being handled. Also, before and after the actual deposition process, the handling of the objects to be coated and of targets needs to be performed in controlled conditions and under controlled gas atmosphere, which handling includes bringing objects and targets into the volume limited by the chamber walls and removal from the volume limited by the chamber walls, in order to avoid detrimental reactions and contamination of materials.

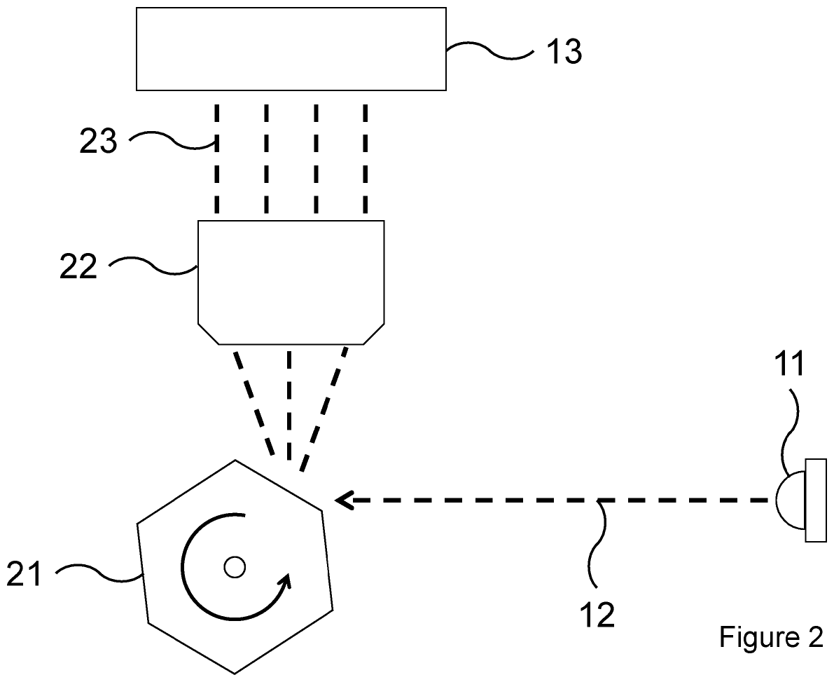

To improve homogeneity and productivity, it would be preferable to produce as wide a material flow as possible from the target to the substrate. In an example of the invention, this can be realised by dividing the laser beam by turning mirrors to form a laser beam array in one plane, which results in formation of a line on the plane of the surface of the target. A possible implementation for this arrangement has been illustrated in FIG. 2. Instead of the target, the laser beam 12 of the laser source 11 is first directed to the moving and/or turning mirrors 21, which can be, for example as shown in the figure, a hexagonal and rotatable polygon having faces with mirror surfaces. The laser beam 12 is reflected from the mirrors 21 to form a fan-shaped laser beam distribution and the reflected beams are directed to the telecentric lens 22. By means of the telecentric lens 22, the laser pulse array can be aligned to form an array 23 of essentially parallel laser beams so that the laser beams hit the target 13 at the same angle. In the plane of observation of the example in FIG. 2, the said angle is 0° with respect to the normal of the surface. Detachment of the material in the same way at each point of incidence of the laser beam is possible if the intensity distribution of the laser beam is the same at each point of incidence.

The laser beam array can also be generated by other means, e.g. a rotating monogon mirror, which directs the laser beams, for example, to an annular target, from which a ring shape material flow is formed.

In an application example a part of the lithium battery, Li-ion battery, or Li-ion capacitor is well suited to be deposited so that material is unwound from a roll to be coated over a desired width in the deposition chamber. A view of principle is shown of this application alternative in FIG. 3. Material is directed at the desired coating width from one or several coating sources onto one or several surfaces of the object to be coated so that material is constantly unwound from the roll for coating and, after it has passed the deposition zone, the material is again collected to a roll. The method can be called a roll-to-roll method, as has already been stated above. In other words, the part 32 to be coated is initially wound in the roll 31a. The ablation apparatus including the laser sources 11 and the target materials 13 is included as has been stated above. The laser beam 12 causes the material to detach as a flow 14 (i.e. in the form of a material flux) towards the material 32 to be coated, and as a result of adherence, the coated part 33 is produced. The coated web 33 is allowed to wind around the second roll 31b, the direction of motion of the web being from left to right in the situation illustrated in FIG. 3. The roll structures 31a, 31b can be motor-driven. Seen in the direction of depth in the figure (transverse direction), the object to be coated can be the entire area of the surface, or only part of the surface. Likewise, in the direction of motion of the web (machine direction), a desired part (length) of the web can be selected to be coated, or alternatively, the entire roll can be gone through from beginning to finish so that the web throughout the entire length of the roll becomes coated. In the case of a membrane material, either only one side or both sides can be coated entirely or, as described above, partially in the machine direction and/or transverse direction.

FIG. 4a is a structural view of an arrangement, in which material is deposited onto a substrate by using laser ablation deposition technology. The laser beam 41 has here been marked with thick dashed lines in the lower part of the figure, and the laser beam arrives to the picture area from bottom right. The laser beam is directed onto the surface of the target material piece 42a, and preferably the direction of the target surface encountered by the beam is preferably set in an inclined direction in relation to the direction of arrival of the beam. The material flow 43a consisting of particles, atoms and/or ions is formed as a result of this interaction. This material flow is shown as linearly traveling and expanding material cloud in the figure. The substrate 44 to be coated is positioned uppermost, and the actual coating 45a is formed on its lower surface, which coating is shown as a rectangle in this figure. In other words, the material flow hits the lower surface of the substrate and is attached to it forming a dense coating in this case.

FIG. 4b illustrates a structural view of an arrangement, in which a porous coating is produced. The arrangement is otherwise the same as in FIG. 4a, but here the material flow 43b consists mostly of particles, and the coating 45b formed on the substrate 44 is porous. In this example, the target 42a used is composed of one material, and there is one target to be used.

FIG. 4c illustrates a structural view of an arrangement, in which a coating with composite structure is produced. The arrangement is otherwise the same as in FIGS. 4a-4b, but here the target 42b has a composite structure and is composed of two different materials. For example, the target 42b could have been made by mixing two different powders, and by compacting them into a solid piece. In this situation, the materials preserve their composition in the material flow 43c, and the composite material coating 45c formed on the lower surface of the substrate 44 is composed of two different materials. The structure of the coating layer 45c can be dense or porous.

FIG. 4d illustrates production of a compound material coating layer using the same principle as in FIG. 4c. When compared to the situation in FIG. 4c, the difference is that materials of the target 42b with composite structure react with each other in the material flow 43d and form a compound. The coating 45d formed on the lower surface of the substrate 44 is a compound formed from two different materials. The structure of the coating layer 45d can be dense or porous.

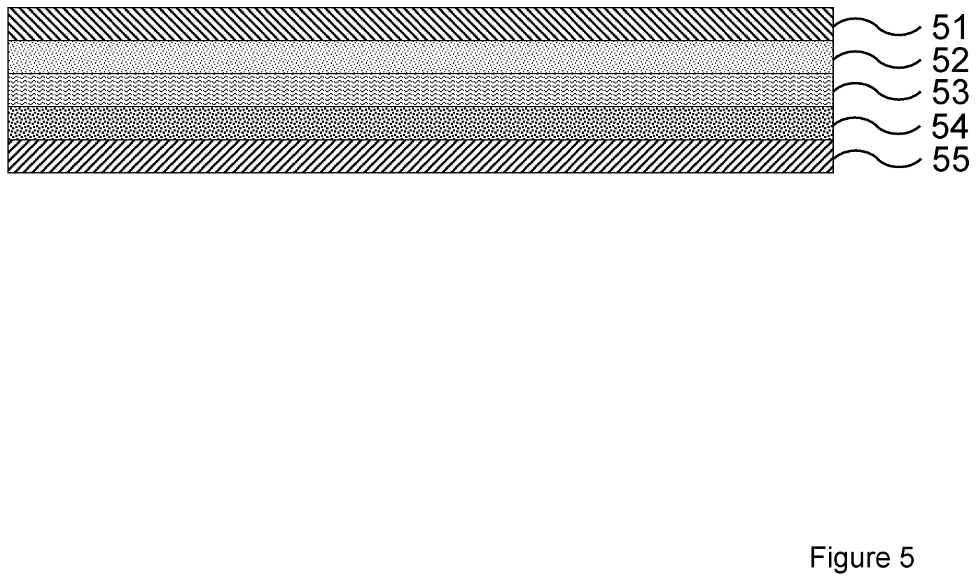

FIG. 5 illustrates a typical structure of a lithium-ion battery as a cross-sectional view. Of the parts, the first one from the top is the aluminium foil 51, which functions as a current collector for the electric current. Moving down, the next part is the cathode material 52. Next there is the porous polymer membrane 53, which functions as separator film in the battery. It can be made, for example, of polyethylene and it can be coated, for example, with ceramic material. The fourth film is the anode material 54. The lowermost, fifth film is the copper film 55, which functions as current collector in a respective way as the uppermost aluminium film 51.

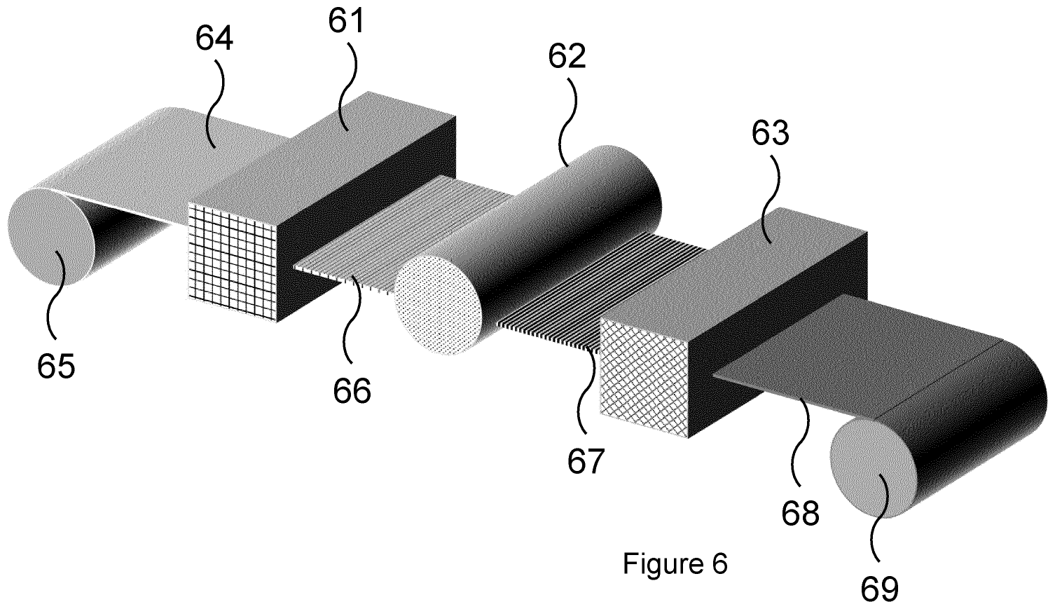

FIG. 6 illustrates a simplified diagram of an exemplary roll-to-roll manufacturing arrangement in one possible embodiment of the invention. In the example of FIG. 6, there are three separate processing stations 61, 62, 63 which have been positioned in a row so that unprocessed substrate is unwound from a roll 65, and after the material deposition taking place in the first station 61, the product 66 including the substrate and first coating material is processed, for example, by heat treatment and/or by laser light and/or by mechanical means in the second station 62. The processed product 67 moves on to the third station 63 where a second coating layer is deposited, after which the product 68 is wound on a roll 69. Within the same process line, between the unwinding and winding roll, it is possible to include also other processing stations, in which, for example, preconditioning and cleaning of the substrate could be performed before deposition. On the other hand, the product could be wound on a roll after each separate process step and transferred to the next processing at the next processing station. The described sequencing can be optimised based on the materials used.

In an embodiment of the invention, the three processing stations in FIG. 6 are deposition of metallic lithium in the first step, processing of the layer of metallic lithium by laser light in the second step, and producing a protective layer on the surface of the metallic lithium in the third step.

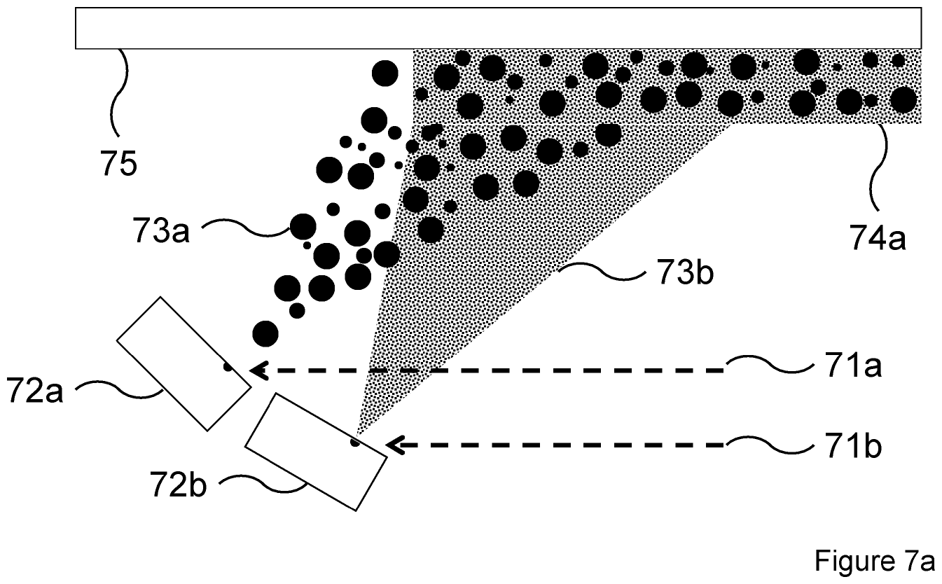

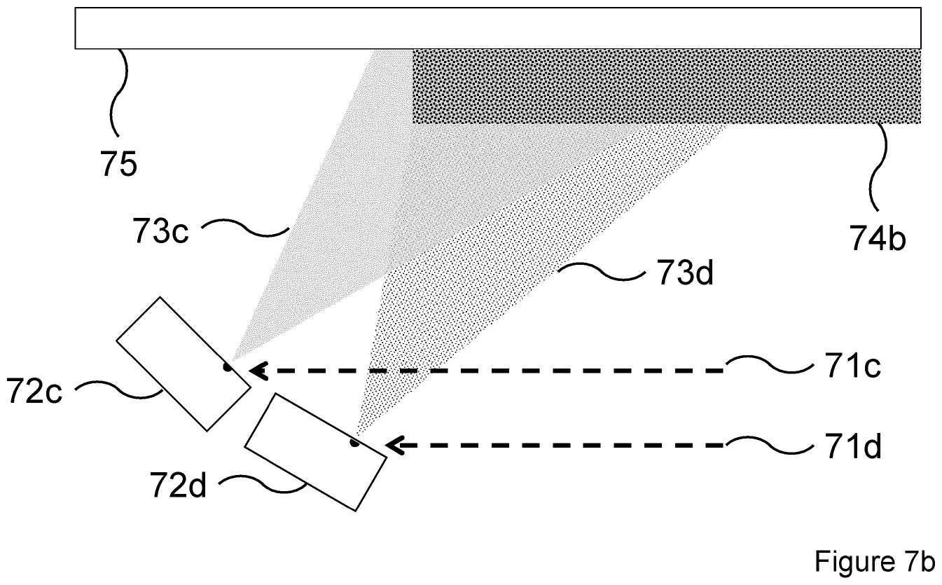

FIG. 7a illustrates an example of a combinatorial coating method using two simultaneous material flows to form a composite coating. Here, two separate laser beams, i.e., the first laser beam 71a and the second laser beam 71b enter the arrangement, and these beams are directed to hit the target material pieces, i.e., the first target 72a and the second target 72b. The material of the first target is different from the material of the second target. Of these interactions, the material flows 73a and 73b are formed as the result of laser ablation. Both these material flows comprise mostly particles in non-reactive form and, additionally, atoms and/or ions, but concerning different materials. The material flows advance simultaneously and partly within the same volume before hitting the lower surface of the substrate 75, thus forming the composite coating 74a which has mainly two different materials distributed homogeneously. The proportions of the different substances in the composite coating 74a can be varied, for example, by independently adjusting either one or both of the laser sources, which generate the laser beams 71a and 71b. The composite coating 74a, the term including also coatings composed of doped materials, is thus formed from the material flows 73a and 73b on the lower surface of the substrate 75 principally in one step and immediately as a finished coating.

FIG. 7b illustrates an example of a combinatorial coating method using two simultaneous material flows to form a compound coating. Here, two separate laser beams, i.e. the first laser beam 71c and the second laser beam 71d enter the arrangement, and these beams are directed to hit the target material pieces, i.e. the first target 72c and the second target 72d. The material of the first target is different from the material of the second target. Of these interactions, the material flows 73c and 73d are formed as the result of laser ablation. Both these material flows comprise mostly components in reactive form but concerning different materials. The material flows advance simultaneously and partly within the same volume before hitting the lower surface of the substrate 75, thus forming the compound coating 74b which has mainly compound formed from two different materials. The proportions of the different substances in the compound coating 74b can be varied, for example, by independently adjusting either one or both of the laser sources, which generate the laser beams 71c and 71d. The compound coating 74b is thus formed from the material flows 73c and 73d on the lower surface of the substrate 75 principally in one step and immediately as a finished coating.

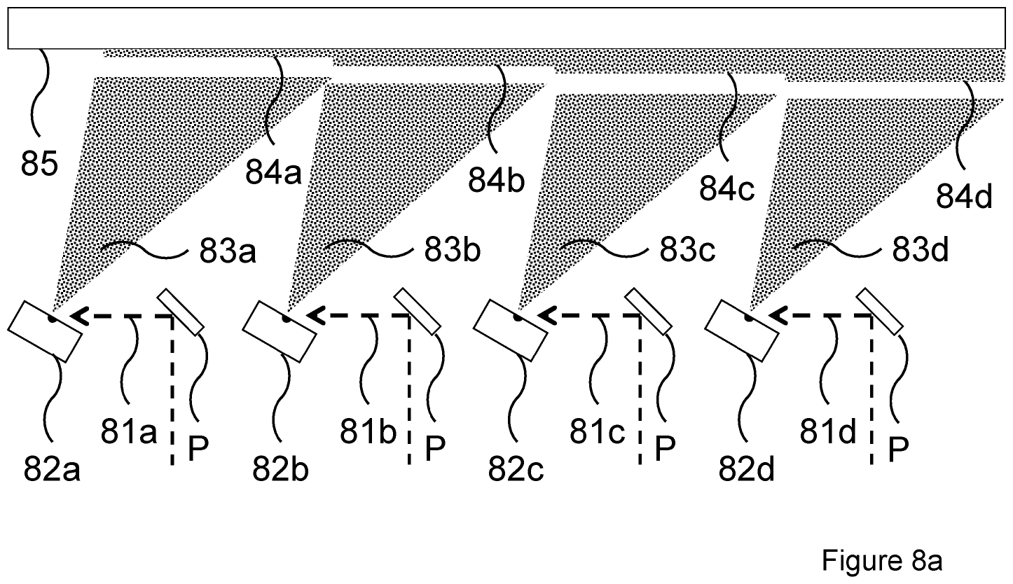

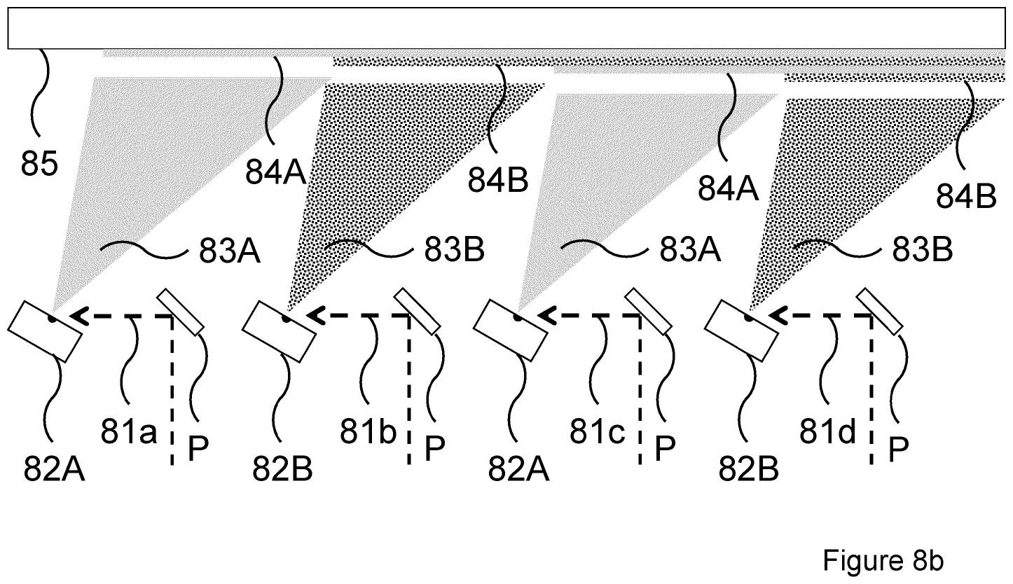

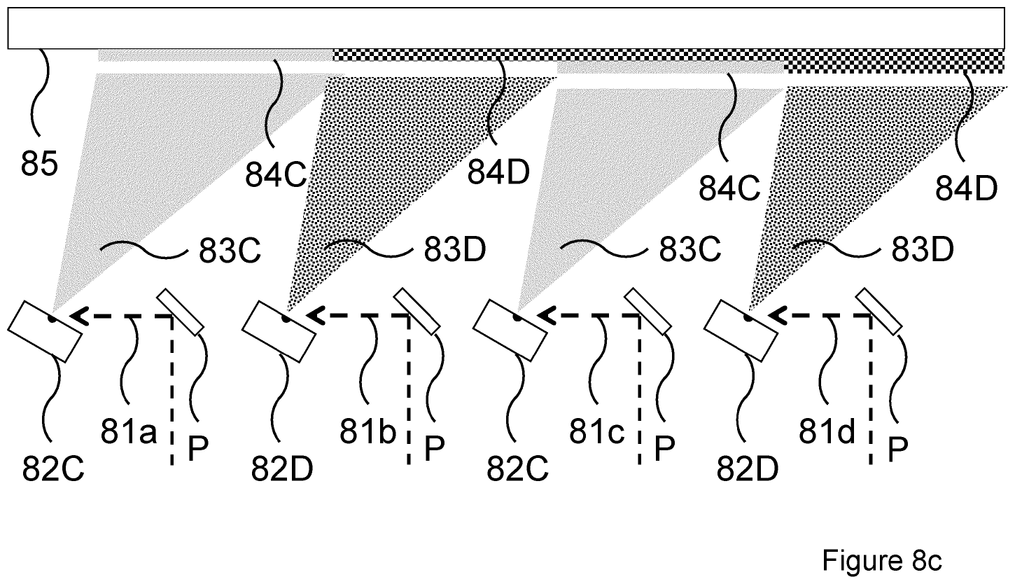

FIG. 8a illustrates the use of successive deposition stations to improve productivity. In this example, four deposition stations are shown, and each incoming laser beam (or pulse string) 81a-d is directed to the appropriate target 82a-d by a mirror (P, each beam having its own). In this situation, the roll-to-roll method can be used, and the lower surface of the substrate 85 first encounters the first material flow 83a, of which the first coating layer 84a is formed. This first coating layer 84a again encounters the second material flow 83b as the substrate 85 moves to the right in the figure, and this way the second coating layer 84b is produced onto the first coating layer 84a. This process continues in the two remaining coating stations, and the final result is the substrate 85 which has encountered the four material flows 83a-d, and this coating has a layered structure 84a, 84b, 84c, 84d. The targets 82a-d can be of the same material, as has been shown in this figure.

FIG. 8b illustrates the use of successive coating stations to improve productivity in the manufacture of composite and multi-layer structures. This is otherwise similar to the situation in FIG. 8a, but now two different types of materials have been selected as the target material pieces 82A, 82B, and these are positioned alternately, one target to one coating station, and the next target being of the second material. In other words, seen from the left, the first and third target are of the same first material “A”, and the second and fourth target, respectively, are of the same second material “B”. The laser beams 81a-d can still be controlled independently and directed on the targets by the mirrors P. This arrangement provides two different types of material flows 83A, 83B, which alternate. When the material flows hit the moving substrate 85, a new different layer is formed on top of the older layers, and the final result is the 4-layered composite structure 84A, 84B, 84A, 84B visible in the right edge of the figure. In this coating, the material layers thus alternate with each other.

FIG. 8c illustrates the use of successive coating stations to improve productivity in the manufacture of doped material. This arrangement is otherwise similar to the one in FIG. 8b, but here the first and third target 82C are made of the basic material, and the second and fourth target 82D, respectively, are made of the additive, i.e., doping material. The laser beams 81a-d can still be controlled independently, and they can be directed on the targets by the mirrors P. This arrangement produces two material flows 83C, 83D of different types, which alternate. With the respective principle as above, the doped basic material now forms the coating to the substrate 85, and the relative proportion of doped material of the entire coating can be chosen by independently adjusting the laser parameters. In the coating layers, 84C represents the basic material layer and 84D the additive layer.

As has emerged in many situations above, in addition to the manufacturing method, the inventive idea of the invention further comprises the manufactured product, i.e. foil or film-type electrode (anode or cathode), and also the essential components of the entire lithium battery, Li-ion battery, or Li-ion capacitor, of which at least one part containing lithium has been manufactured using laser ablation.

As a summary, in the invention, a material coating layer of a part of an electrochemical energy storage device is produced so that at least one of the targets used in laser ablation deposition contains lithium as metal or in a compound or alloy, and so that at least one material coating layer containing lithium is produced by laser ablation deposition method. Finally, the device, i.e. lithium battery, Li-ion battery, or Li-ion capacitor, is assembled comprising a part which has one or more material layers produced by laser ablation.

Combinatorial deposition arrangements and successive deposition stations according to FIGS. 7a, 7b, and 8a can be combined so that, for example, one deposition arrangement of another type has been taken in the place of one or some deposition stations in FIG. 8a, such as a combinatorial deposition station comprising two or several targets in accordance with the principle of the example in FIG. 7a. The successive and combinatorial deposition arrangements can be combined also so that, in place of one or several material sources, some other suitable coating method is used instead of the laser ablation deposition method.

In the following, features of the invention are further compiled in a list-type form in the way of a summary.

The invention relates to a method for manufacturing materials containing lithium, the method comprising the steps of
directing a laser beam (12, 23, 41, 71a-d, 81a-d) to at least one target (13, 42a-b, 72a-b, 82a-d, 82A-D) containing lithium and/or lithium compound;
detaching at least one material (14, 43a-d, 73a-d, 83a-d, 83A-D) from at least one target (13, 42a-b, 72a-d, 82a-d, 82A-D, 92) by laser ablation;
directing at least one detached material (14, 43-d, 73a-d, 83a-d, 83A-D) to the substrate (15, 32, 44, 64, 75, 85) of the deposition to at least one surface or part of the surface;
the energy delivered to the target by the laser beam and/or the surface area of the laser spot on the target surface is adjusted based on the measurement of the electromagnetic radiation generated by the laser ablation during the detachment of the material.

A characteristic feature of the invention is that the method further comprises the step
a part of a lithium battery, Li-ion battery, or Li-ion capacitor is produced so that at least one material layer containing lithium is produced by laser ablation deposition.

In an embodiment of the invention, a lithium battery, Li-ion battery, or Li-ion capacitor is further assembled in the method by using parts which comprise an anode, cathode, and a solid or liquid electrolyte material, so that at least one of the parts has a material layer manufactured by using laser ablation deposition.

In an embodiment of the invention, when using laser ablation deposition, the detachment of material, formation of particles and transfer of material from the target (13, 62, 72a-d, 82a-d, 82A-D) to the substrate (15, 32, 44, 64, 75, 85) is achieved by a laser beam (12, 23, 41, 71a-d, 81a-d) which is pulsed, directed on the target (13, 42a-b, 72a-d, 82a-d, 82A-D), in which the duration of an individual laser pulse is between 0.5-100000 ps (0.5 ps-100 ns).

In an embodiment of the invention, laser pulses are generated at a repetition rate which can be selected in the range 50 kHz-100 MHz.

In an embodiment of the invention, at least one layer containing lithium in metallic form is produced by laser ablation deposition by using a Li-metal target.

In an embodiment of the invention, a layer of lithium with thickness of less than 100 nm is produced by laser ablation deposition by using a Li-metal target.

In an embodiment of the invention, the manufacture of a material layer is performed in at least two sequential successive deposition stations so that at least one of the deposition stations is operating such that the material flow it produces does not encounter another material flow produced either in the preceding or in the subsequent deposition station before it forms a coating layer on the surface of the substrate.

In an embodiment of the invention, a layer of lithium with thickness of less than 100 nm is produced by laser ablation deposition by using a Li-metal target, after which in the next processing step more lithium metal is produced on top of the layer of lithium by using a suitable method.

In an embodiment of the invention, a layer composed essentially of lithium having thickness of 5 μm at most is produced first by laser ablation deposition by using a Li-metal target, after which the deposition is continued with another method to produce a layer composed essentially of lithium having thickness of 100 μm at most.

In an embodiment of the invention, at least two laser beams having different properties are simultaneously directed to a target (13, 42a-b, 72a-d, 82a-d, 82A-D).

In an embodiment of the invention, at least two of the separate laser beams directed to a target (13, 42a-b, 72a-d, 82a-d, 82A-D) have their spots partially overlapping on the surface of the target and interact simultaneously on the surface of the target.

In an embodiment of the invention, two laser beams of which the first one is a pulsed laser beam and the second one a continuous wave laser beam are simultaneously directed to a target (13, 42a-b, 72a-d, 82a-d, 82A-D).

In an embodiment of the invention, a layer of lithium is produced by laser ablation deposition by using a Li-metal target so that the area where the laser beam hits has lithium in liquid form.

In an embodiment of the invention, after the manufacturing of the material, the material layer is modified by directing a laser beam on it.

In an embodiment of the invention, at least one layer comprising essentially lithium in metallic form is produced by laser ablation deposition by using a composite target (42b) containing Li metal.

In an embodiment of the invention, at least one layer comprising essentially lithium bound in a compound is produced by laser ablation deposition by using a composite target (42b) containing Li metal.

In an embodiment of the invention, at least one layer comprising essentially lithium bound in a compound is produced by laser ablation deposition by using a composite target (42b) containing Li metal and electrode material.

In an embodiment of the invention, the deposition of the active electrode material is performed by using a target which comprises, in addition to an electrode material and/or lithium and/or a lithium compound, either metallic materials and/or carbon, in which, in the case metallic materials are utilised, the metallic materials comprise at least 25 weight percents of either copper, silver, iridium, gold, tin, nickel, platinum or palladium or an alloy of at least two of the listed metals.

In an embodiment of the invention, the above-mentioned electrode material is one or several of the following:

Carbon (carbon particles, carbon nanotubes, graphene, graphite), Li₄Ti₅O₁₂, TiO₂, Si, LiSi compounds, LiSiO, Sn, Ge, silicon oxides SiOₓ, SnO₂, iron oxides, cobalt oxides, metal phosphides and metal sulphides, Si—Sn, SiSnFe, SiSnAl, SiFeCo, SiB₄, SiB₆, Mg₂Si, Ni₂Si, TiSi₂, MoSi₂, CoSi₂, NiSi₂, CaSi₂, CrSi₂, Cu₅Si, FeSi₂, MnSi₂, NbSi₂, TaSi, VSi₂, WSi₂, ZnSi₂, SiC, Si₃N₄, Si₂N₂O, SiOₓ.

In an embodiment of the invention, the above-mentioned electrode material is one or several of the following: LiCoO₂, LiMnO₂, LiMn₂O₄, LiMnO₃, LiMn₂O₃, LiMn₂₋ₓMₓO₂ (M=Co, Ni, Fe, Cr, Zn, Ta, 0.01<x<0.1), LiNiO₂, LiNi₁₋ₓMₓO₂ (M=Co, Ni, Fe, Mg, B, Ga, 0.01<x<0.3), LiNiₓMn₂₋ₓO₄ (0.01<x<0.6), LiNiMnCoO₂, LiNiCoAlO₂, Li₂CuO₂, LiV₃O₈, LiV₃O₄, V₂O₅, Cu₂V₂O₇, Li₂Mn₃MO₈ (M=Fe, Co, Ni, Cu, Zn), TiS₃, NbSe₃, LiTiS₂, LiFePO₄, Li₂S, MS₂ or MS (M=Fe, Mo, Co, Ti).

In an embodiment of the invention, lithium is produced on a three-dimensional, electron-conducting structure by laser ablation deposition by using a Li-metal target.

In an embodiment of the invention, lithium is deposited on the surface of a metal or metal-alloy layer with thickness of less than 100 nm, which metal layer is not composed of lithium or which metal-alloy layer does not comprise lithium.

In an embodiment of the invention, lithium is deposited on the surface of a metal or metal-alloy layer with thickness of less than 100 nm, which metal or metal-alloy layer comprises one or several metals from the following group: copper, silver, iridium, gold, tin, nickel, platinum, or palladium.

In an embodiment of the invention, lithium compound or lithium metal is deposited on the surface of at least one electrode material by laser ablation deposition.

In an embodiment of the invention, by using successive deposition stations, in a subsequent deposition step, a protective layer is produced on top of a layer produced by laser ablation deposition and containing lithium or lithium compound.

In an embodiment of the invention, the above-mentioned protective layer is one or several of the following group: LLMO (where M=Zr, Nb, Ta), LPS, LGPS, LiPON, oxide such as Al₂O₃, SiO₂, TiO₂, or ZnO, nitride such as TiN, Si₃N₄, or BN, fluoride such as AlF₃, phosphate such as AlPO₄.

In an embodiment of the invention, a coating layer containing lithium has up to 15 volume percents of metal produced by laser ablation or at least 20 weight percents of particles containing metals.

In an embodiment of the invention, a material layer containing at least 25 weight percents of lithium and another metal is produced combinatorially or by using successive deposition stations.

In an embodiment of the invention, the above-mentioned metal is one or several from the following group: copper, silver, iridium, gold, tin, nickel, platinum, or palladium.

In an embodiment of the invention, the particles containing metal have an average size of up to 500 nm.

In an embodiment of the invention, at least one active electrode material used in the deposition, volume fraction of which electrode material in an electrode material coating layer is at least 10 volume percents, has an average particle size of less than 900 nm.

In an embodiment of the invention, an electrode material coating layer comprises at least 10 weight percents of lithium.

In an embodiment of the invention, an electrode material coating layer comprises at least 30 weight percents of lithium.

In an embodiment of the invention, an electrode material coating layer comprises at least 10 weight percents of carbon.

In an embodiment of the invention, an electrode material coating layer comprises at least 15 weight percents of carbon.

In an embodiment of the invention, at least two laser sources are set to operate simultaneously, forming together a combinatorial continuous material flow (73a, 73b) from at least two targets (72a, 72b) to the surface of the substrate (75), thus forming a composite coating (74a) consisting of at least two different materials.

In an embodiment of the invention, at least two laser sources are set to operate simultaneously, forming together a combinatorial continuous material flow (73c, 73d) from at least two targets (72c, 72d) to the surface of the substrate (75), thus forming a compound coating (74b) formed from at least two different materials.

In an embodiment of the invention, a carbon-based material is deposited in a combinatorial manner in at least one deposition step by pulsed laser ablation deposition together with a material containing lithium.

In an embodiment of the invention, the total thickness of the electrode material coating layer is at most 100 μm.

In an embodiment of the invention, the quantity of metallic materials in a target is at most 15 weight percents.

In an embodiment of the invention, the quantity of carbon in a target is at most 90 weight percents.

In an embodiment of the invention, the porosity of an electrode material coating layer is at least 5 volume percents.

In an embodiment of the invention, the porosity of an electrode material coating layer is at least 20 volume percents.

The inventive idea further comprises an electrochemical device (a lithium battery, a Li-ion battery, or a Li-ion capacitor) which comprises a cathode material and an anode material. It is characterised in that the device further comprises either a solid or liquid electrolyte, and in which at least one embodiment option of the method described above has been utilised in the manufacture of a coating layer containing lithium.

In an embodiment of the invention, in the assembly phase of the device, the material layers of an electrochemical device contain active (i.e., available for the reactions required in the basic operation of the device) lithium an amount which exceeds the storage capacity of the cathode material present in the device.

In an embodiment of the invention, in the assembly phase of the device, the material layers of an electrochemical device contain active lithium an amount which exceeds the storage capacity of the cathode material present in the device such that, during the usage of the device, the excess lithium is stored in the active anode material which additionally has free Li-ion/lithium storage capacity at least equal to the capacity of the cathode.

In an embodiment of the invention, in the assembly phase of the device, the material layers of an electrochemical device contain metallic lithium which is consumed in irreversible reactions and/or, after taking part in the ion exchange, is stored in the electrode materials without forming metallic lithium at a later stage when the device is being used.

In an embodiment of the invention, in the assembly phase of the device, the material layers of an electrochemical device contain active lithium an amount which exceeds the storage capacity of the cathode material present in the device such that, during the first operational cycle (the transition of Li ions from an electrode to another and back) of a device assembled ready for operation and during the phases preceding the first operational cycle, favorably 50-100%, more favorably 70-100%, even more favorably 80-100%, and most favorably 90-100% of the Li content exceeding the storage capacity of the cathode is consumed in irreversible reactions.

The method according to the invention has the following advantages:
i. Material layers containing lithium or lithium compounds can be produced with a simple arrangement into structures without damaging or contaminating materials
ii. Material layers can be produced at a low temperature and without damaging the substrate
iii. Good adhesion is achieved between different material layers without special adhesion layers or binders
iv. The amount of lithium in the coating layer can be controlled accurately
v. New electrode materials, appropriate and full-fledged utilisation of which requires introducing additional lithium into the structures, can be manufactured and put to use
vi. Electrode materials storing lithium in compound form can be transferred to electrode layers in the form containing lithium, so that the detrimental effects caused by the volume changes in the electrode materials generated by the charge-discharge cycles related to the operation of the battery can be minimised
vii. Composite materials can be manufactured for producing the optimal combination of different materials
viii. It is possible to perform doping in order to add small quantities of doping substances, for example, to improve electrical conductivity
ix. Layered structures can be manufactured to optimise the properties
x. Several material layers essential for different functionalities can be manufactured with one manufacturing method and partially even in one manufacturing step
xi. During the production of different material layers, there is no risk for the materials becoming damaged or contaminated, if the layers are produced with one apparatus
xii. Reaction sensitive surfaces and materials (such as lithium) can be protected by one or several protective layers in the same process
xiii. The use of binders can be avoided, which reduces the contamination of battery chemistry in long-term operation
xiv. The correct composition of the coating layers can be preserved in the transfer from target to coating layer
xv. Open area and porosity of the active electrode material can be adjusted by tuning laser parameters, background gas or its pressure, and the distance between the target and the substrate
xvi. The process can be controlled precisely based on collecting and measuring the electromagnetic radiation generated by the laser ablation, which enables repeatability and homogeneous quality of the process in industrial manufacturing
xvii. The quantity of productional investments can be reduced
xviii. Electrode materials with a very small particle size (<1 μm) can be manufac-tured, which
   a. Increases the quantity of active surface in contact with the electrolyte
   b. Shortens the diffusion length of ions and electrons
   c. Decreases the cracking sensitivity of the electrode material particles due to volume changes during the discharge and charge steps
xix. The result is a fine structure, in which the optimised pore distribution better withstands the volume changes occurring during the discharge and charge of the battery without cracking
xx. It is possible to manufacture amorphous materials, which better withstand the volume changes caused by charge/discharge cycles without cracking or damages with certain materials (for example, silicon)
xxi. A homogeneous pore distribution reduces the stresses generated by the volume changes caused by charge/discharge cycles
xxii. It is possible to manufacture batteries with a considerably higher energy density when compared to the conventional material solutions

In the invention, it is possible to combine individual features of the invention mentioned above and in the dependent claims into new combinations, in which two or several individual features can have been included in the same embodiment.

The present invention is not limited only to the examples shown, but many varia-tions are possible within the scope of protection defined by the enclosed claims.

1. A method for manufacturing a material layer comprising lithium (Li), the method being carried out using equipment comprising:
a chamber, within which composition and pressure of the gas are controllable, and handling of the materials is performed in controlled conditions and under controlled gas atmosphere, the handling comprises bringing materials into the volume limited by the chamber walls and removing from the volume limited by the chamber walls,
at least one laser source, which generates a laser beam,
at least one optical component, which is utilised to affect optical properties of the laser beam,
at least one optical component, which is utilised to change direction of the laser beam,
at least one lithium-comprising target is setup in the chamber,
a device, which is utilised to move the target located inside the chamber,
a selected surface area on the target is arranged for process by the laser beam,
at least one laser beam is directed to hit the surface of the lithium-comprising target and to detach lithium-comprising material from the target so that material is detached from a desired area on the surface of the target by means of movement of the target and/or controlling the laser beam,
a substrate to be coated is setup in the chamber,
a device, which is utilised to move the substrate located inside the chamber,
the substrate is controlled such that lithium-comprising material detached by laser ablation from the target is hitting on the desired surface area on the surface of the substrate,
a measurement device, which is utilised to measure the electromagnetic radiation generated by laser ablation;
the method comprising the following steps:
forming a lithium-comprising layer of selected thickness, on said surface area on the surface of the substrate,
processing and modifying the formed lithium-comprising layer by thermal treatment, by laser light, or mechanically, by a device configured to process and modify materials, and
adjusting energy delivered to the target by the laser beam and/or adjusting the surface area of the laser spot on the target surface based on the measurement of the electromagnetic radiation generated by the laser ablation during the detachment of the material.

2. The method according to claim 1, wherein the substrate is a current collector, solid-state electrolyte, or separator.

3. The method according to claim 1, wherein the method further comprises the step of assembling a lithium battery, Li-ion battery, or Li-ion capacitor by using manufactured material layers comprising an anode, cathode, and a solid or liquid electrolyte material, and using pulsed laser ablation deposition to manufacture at least one lithium-comprising layer.

4. The method according to claim 1, comprising producing material on the substrate of the coating process in layered fashion so that at least one layer is substantially Li metal.

5. The method according to claim 1, comprising performing manufacturing of the material layers in at least two successive deposition stations so that at least one of the deposition stations is operating such that a material flow produced does not encounter another material flow produced either in a preceding or in a subsequent deposition station before the material flow forms a coating layer on the surface of the substrate.

6. The method according to claim 1, wherein a layer substantially of Li metal with thickness of less than 5 μm is first produced by laser ablation deposition on the surface of the substrate, after which deposition continues with another method to produce a layer substantially of Li metal with total thickness of 100 μm at most.

7. The method according to claim 1, wherein at least two separate laser beams having different properties are simultaneously directed to a lithium-comprising target.

8. The method according to claim 7, wherein at least two of the separate laser beams directed to the lithium-comprising target have spots partially overlapping on the surface of the target and interact simultaneously on the surface of the target.

9. The method according to claim 1, wherein at least two laser sources are set to operate simultaneously, and material is produced on the surface of the substrate simultaneously from at least two different targets in a same environment so that the material flows from the targets to the substrate encounter each other before the material flows form a coating layer on the surface of the substrate.

10. The method according to claim 1, wherein at least one of the targets used in the deposition is structurally a composite and comprises Li metal.

11. The method according to claim 10, wherein during the laser ablation process and when the material layer is formed, components of the Li composite form together at least one Li compound.

12. The method according to claim 1, wherein a layer of lithium is produced by laser ablation deposition by using a Li-metal target so that an area on the target where the laser beam hits has lithium in liquid form.

13. The method according to claim 1, wherein on top of at least one lithium-comprising material layer, a protective layer is deposited in one of the subsequent processing steps.

14. The method according to claim 1, wherein lithium is deposited on the surface of a metal or metal-alloy layer with thickness of less than 100 nm, which metal or metal-alloy layer comprises one or more metals from the following group: copper, silver, iridium, gold, tin, nickel, platinum, or palladium.

15. An electrochemical energy storage device utilising lithium, which device comprises:
a. a cathode material, and
b. an anode material,
c. either a solid or liquid electrolyte, and
d. wherein the method according to claim 1 is utilised in manufacturing of at least one material layer.
